(19) United States
(12) Patent Application Publication
(10) Pub. No.: US 2011/0124146 A1
(43) Pub. Date: May 26, 2011

(54) METHODS OF FORMING HIGH-EFFICIENCY MULTI-JUNCTION SOLAR CELL STRUCTURES

(76) Inventors: Arthur J. Pitera, Brookline, MA (US); Eugene A. Fitzgerald, Windham, NH (US); Steven A. Ringel, Bexley, OH (US)

(21) Appl. No.: 12/790,078

(22) Filed: May 28, 2010

Related U.S. Application Data
(60) Provisional application No. 61/182,344, filed on May 29, 2009.

(51) Int. Cl. H01L 31/18

(52) U.S. Cl. 438/64; 438/94; 257/E31.019; 257/E31.11

(57) ABSTRACT

In various embodiments, solar cells include a junction including SiGe, a junction including at least one III-V material, and may be formed on silicon substrates and/or with silicon-based capping layers thereover.

### CROSS-REFERENCE TO RELATED APPLICATION

This application claims priority to and the benefit of, and incorporates herein by reference in its entirety, U.S. Provisional Patent Application Ser. No. 61/182,344, which was filed on May 29, 2009.

### TECHNICAL FIELD

The present invention relates, in various embodiments, to the construction and fabrication of high-efficiency solar cells.

### BACKGROUND

Widespread deployment of environmentally benign power-generation systems, such as those based on solar energy, depends critically on the ability to achieve high power-conversion efficiencies, e.g., the percentage of sunlight that can actually be captured and converted into electricity. III-V compound semiconductors have historically produced solar cells with the highest power-conversion efficiencies. The superior performance of these materials is made possible through bandgap and lattice-constant engineering in the III-V material system. By alloying III-V semiconductors, multiple bandgaps are possible at the same lattice constant, leading to multi-junction solar cells with superior efficiency levels. However, the flexibility of the III-V system is limited by the need to match the lattice constants of all the layers in the multi-junction stack in order to preserve the high material quality of the active regions. Furthermore, the bandgaps for building an optimal multi-junction solar cell are not available at the lattice constant of conventional substrate materials such as Si, Ge, GaAs, and InP. For example, a state-of-the-art Ge/GaAs/InGaP multi-junction cell uses bandgaps (0.67/1.4/1.8 eV) that are suboptimal for efficiency, but are nonetheless used because all of the layers are conveniently lattice-matched to a Ge substrate.

Besides the potential of III-V multi-junction solar cells to achieve high efficiencies, the number of practical applications for high-efficiency solar technology increases as cost and weight decrease. Currently, silicon-based cells are low-cost relative to III-V multi-junction cells because silicon-based solar and electronics manufacturing is scaled to much larger volumes, making the per-unit cost of a solar cell much less expensive. In contrast, current III-V multi-junction cells are more exotic in the industry—deposited on Ge substrates and manufactured in dedicated, relatively low volume 100 mm-diameter-wafer-based facilities. The result is a substantial cost differential: whereas the cost of III-V-junction solar cells is measured in dollars per square centimeter, silicon technology cost is measured in dollars per square meter. In addition, Ge is approximately twice the density of silicon, and is therefore a much heavier substrate for multi-junction III-V technology. This has particular disadvantages for flight applications (e.g., satellites and solar-powered aerial vehicles) where specific power (i.e., the amount of power generated per unit weight of the structure) is an important metric.

Multi-junction solar cells can exhibit other disadvantages. The addition of subcells (i.e., multiple junctions) tends to increase efficiency, as each subcell may be optimized for a specific portion of the solar spectrum. As a result, three or more subcells are favored for very high efficiency (>30%) applications. However, the photocurrent produced in multi-junction cells tends to decrease as the number of junctions increases. Furthermore, since the multi-junction current is limited by the subcell that produces the least amount of current (and each subcell is optimized for a specific portion of the solar spectrum), multi-junction cells suffer from spectral sensitivity where changes in the spectrum, such as that arising from the change in the position of the sun in the sky throughout the day, will reduce the efficiency of the cell. This effect is a concern for all terrestrial applications (as well solar-powered aerial vehicles) where the solar spectrum tends to vary among approximately air-mass-zero (“AM0,” corresponding to the solar spectrum outside the atmosphere of the earth) or air-mass-one (“AM1,” corresponding to the solar spectrum on the surface of the earth when the sun is directly overhead) to air-mass-1.5 (“AM1.5,” corresponding to the solar spectrum on the surface of the earth with a solar zenith angle of approximately 48°) to greater than air-mass-ten (“AM10,” corresponding to the solar spectrum on the surface of the earth as the sun sets on the horizon).

State-of-the-art cells utilize three optimized junctions to achieve very high efficiency (approximately 30%) at the expense of increased spectral sensitivity. Furthermore, solar cell designs utilizing four or more junctions have been proposed to achieve even higher efficiencies (approaching 40%); however, these designs have even greater sensitivity to spectral variation owing to their large number of subcells. Further improvements to multi-junction solar cell efficiency and spectral sensitivity have been hampered due to the lack of high-quality, optimized-bandgap materials on conventional substrate materials.

Thus, in order to meet the demand for inexpensive, highly efficient solar-cell technology, improved structures and methods for fabricating III-V-based solar cells in a silicon-based manufacturing environment are needed. Such structures should reduce both weight and cost, and produce very high power outputs with minimal sensitivity to spectral variation.

### SUMMARY

Embodiments of the present invention feature methods of forming high-efficiency, multi-junction solar cells that exhibit minimal sensitivity to spectral variation, e.g., a three-junction cell having maximum efficiencies exceeding 40% at the AM0 spectrum and 50% at the AM1.5 spectrum, and/or a two-junction cell having a spectral sensitivity less than approximately 2.1% (i.e., a cell whose efficiency changes by less than approximately 2.1% with changes in the solar spectrum, e.g., from AM0 to AM1.5). The cells may be advantageously fabricated on Si substrates (which are lightweight, inexpensive, and have large diameters) and may be processed in Si-compatible manufacturing facilities. Generally, the multi-junction cells feature a junction including or consisting essentially of SiGe (e.g., rather than pure Ge or pure Si), as well as one or more junctions including or consisting essentially of III-V semiconductor materials.

Furthermore, limitations of conventional solar cell technology and fabrication processes are herein addressed by solar cell devices having SiGe- and III-V-based active junctions “encapsulated” by silicon, i.e., multi-junction solar cells produced on silicon substrates and having silicon-based capping layers. These may be produced utilizing techniques similar to those disclosed in U.S. Patent Application Publication Nos. 2010/0116942 and 2010/0116329, the entire disclosure of each of which is incorporated by reference herein. Silicon encapsulation not only enables the fabrication of optimized junctions on larger, lower-density substrates, but also allows the solar cells to be fabricated in silicon-dedicated facilities.

In an aspect, embodiments of the invention feature a solar cell including a substrate, a first junction disposed over the substrate, a second junction disposed over the first junction, and a cap layer disposed over the second junction. The substrate and/or the cap layer may include or consist essentially of doped and/or undoped silicon. The first junction may include or consist essentially of SiGe, and the second junction may include or consist essentially of at least one III-V material. The first junction and/or the second junction may have a threading dislocation density of less than approximately 10⁷ cm⁻².

Embodiments of the invention may include one or more of the following features in any of a variety of combinations. The III-V material may include or consist essentially of at least one of GaAs, InGaP, AlGaP, AlGaAs, GaP, AlGaSb, GaSb, InP, InAs, InSb, InAlGaP, GaAsP, GaSbP, AlAsP, or AlSbP. The cap layer may consist of doped or undoped silicon. The cap layer may include or consist essentially of a first layer including or consisting essentially of doped or undoped silicon and, disposed thereunder, a second layer including or consisting essentially of at least one of GaP or AlP (doped or undoped). The first and second layers may be in direct contact. The cap layer may include or consist essentially of silicon doped p-type at a doping level greater than approximately 1×10¹⁹ cm⁻³, and the cap layer may be disposed over and in direct contact with a portion of the second junction that is doped n-type.

The solar cell may include a recess in a surface of the substrate opposed to the first and second junctions. The recess may be substantially filled with at least one non-silicon material, which may include or consist essentially of a metal and/or have a density less than that of silicon. The thickness of the cap layer may be less than an absorption length of solar photons in silicon.

The solar cell may include a third junction disposed between the second junction and the cap layer. The third junction may include or consist essentially of at least one III-V material and have a bandgap different from the bandgaps of the first junction and the second junction. The first junction and the second junction (and the third junction, if present) may be substantially lattice-matched to each other. The first and second junctions may each have a lattice mismatch to Ge of greater than approximately 1%.

A contact may be disposed over and/or in direct contact with the cap layer. The contact may include or consist essentially of an alloy of silicon and a metal. The metal may include or consist essentially of at least one of titanium, copper, nickel, cobalt, platinum, or tungsten. The metal may consist essentially or consist of nickel. An anti-reflection coating may be disposed over the cap layer. The anti-reflection coating may include or consist essentially of at least one of silicon nitride and silicon dioxide.

A template layer having a threading dislocation density less than approximately 10⁷ cm⁻² may be disposed over the substrate. A top surface of the template layer may be substantially lattice-matched to the first junction. The template layer may include or consist essentially of a graded-composition layer. The graded-composition layer may include or consist essentially of doped or undoped SiGe. The first junction, second junction, third junction, template layer, and/or cap layer may be disposed over substantially all of the top surface of the substrate.

A spectral sensitivity of the solar cell may be less than approximately 6%, or even less than approximately 2%, for a change in spectrum from AM0 to AM1.5. The second junction may be substantially free of Al (e.g., at least in active regions thereof). The first junction may produce a current of greater than approximately 0.2 V, greater than approximately 0.5 V, or even greater than approximately 0.8 V in operation. In operation, the first junction may produce at least as much current as the second junction. The first junction may be partitioned into at least two sub-cells, each sub-cell including or consisting essentially of SiGe having a different Ge concentration than the other sub-cells. At least an upper portion of the first junction may be doped with an element not in the second junction, e.g., boron. The interface between the first junction and the second junction may be substantially free of oxygen, carbon, anti-phase defects, dislocations, and/or stacking faults. The interface between the first junction and the second junction may include or consist essentially of a SiGe—GaAsP tunnel junction. The at least one III-V material may include or consist essentially of GaAsP, InGaP, GaPSb, and/or InAlGaP.

In another aspect, embodiments of the invention feature a method for forming a solar cell including forming first and second junctions over a substrate and forming a cap layer over the second junction. The substrate and/or the cap layer may include or consist essentially of doped or undoped silicon. The first junction includes or consists essentially of SiGe, and the second junction includes or consists essentially of at least one III-V material. The first junction and/or the second junction may have a threading dislocation density of less than approximately 10⁷ cm⁻².

Embodiments of the invention may feature one or more of the following in any of a variety of combinations. Forming the first junction and forming the second junction (and possibly even forming the cap layer) may include or consist essentially of deposition in a single reactor with substantially no exposure of the substrate to oxygen therebetween. Forming the first junction, the second junction, and/or the cap layer may include or consist essentially of epitaxial deposition. The first junction may be formed in a first chamber and the second junction may be formed in a second chamber different from the first chamber. The first junction and the second junction may be formed in a single chamber. The cap layer may be formed in the first chamber (or the single chamber), or may be formed in a third chamber different from both the first and second chambers.

A portion of the substrate may be removed by thinning and/or waffling. A third junction may be provided between the second junction and the cap layer. The third junction may include or consist essentially of at least one III-V material and have a bandgap different from the bandgaps of the first and second junctions. A template layer may be formed between the substrate and the first junction. The first junction, second junction, third junction, template layer, and/or cap layer may be formed over substantially all of the top surface of the substrate.

A metal may be formed over the cap layer and reacted with at least a portion of the cap layer to form a contact layer disposed over the second junction. The contact layer may include or consist essentially of an alloy of silicon and the metal. An unreacted portion of the cap layer may be removed. The metal may include or consist essentially of at least one of titanium, copper, nickel, cobalt, platinum, or tungsten. The metal may consist essentially or consist of nickel. After reacting the metal with at least a portion of the cap layer, an unreacted portion of the cap layer may remain disposed between the first junction and the contact. The unreacted portion of the cap layer may be substantially free of silicon (except for, e.g., any silicon utilized as a dopant therein). The metal may be reacted substantially throughout a thickness of the cap layer, such that the contact is disposed over the first junction with substantially no unreacted portion of the cap layer therebetween.

Forming the first junction may include intentional introduction of n-type and p-type dopants during epitaxial growth. A tunnel junction may be formed between the first junction and the second junction, and may include or consist essentially of SiGe and/or GaAsP. Forming the tunnel junction may include autodoping, e.g., mutual autodoping or autodoping of only a single dopant species.

In yet another aspect, embodiments of the invention feature a method of power generation including providing a solar cell on a platform and exposing the solar cell to solar radiation, thereby generating an electric current. The solar cell includes or consists essentially of a substrate, a first junction disposed over the substrate, a second junction disposed over the first junction, and a cap layer disposed over the second junction. The substrate and/or the cap layer may include or consist essentially of doped or undoped silicon. The first junction includes or consists essentially of SiGe, and the second junction includes or consists of at least one III-V material. The first junction and/or the second junction may have a threading dislocation density of less than approximately 10⁷ cm⁻².

Embodiments of the invention may feature one or more of the following in any of a variety of combinations. The platform may include or consist essentially of a concentrator system, an aerial vehicle, or a satellite disposed over a substantial portion of the earth's atmosphere. The solar cell may include a third junction disposed between the second junction and the cap layer. The third junction may include or consist essentially of at least one III-V material and have a bandgap different from the bandgaps of the first and second junctions. Exposing the solar cell to solar radiation may include or consist essentially of exposing the solar cell to spectra ranging from approximately AM1 to greater than approximately AM1.5, or even from approximately AM1 to greater than approximately AM10. The spectral sensitivity of the solar cell may be less than approximately 6%, or even less than approximately 2%. The portion of the electric current generated by the first junction may be greater than approximately 0.2 V, greater than approximately 0.5 V, or even greater than approximately 0.8 V. The portion of the electric current generated by the first junction may be at least equal to the portion of the electric current generated by the second junction.

In a further aspect, embodiments of the invention feature an aerial vehicle including an airframe. A solar cell is associated with (and may be in direct contact with) the airframe. The solar cell includes or consists essentially of a substrate, a first junction disposed over the substrate, a second junction disposed over the first junction, and a cap layer disposed over the second junction. The substrate and/or the cap layer may include or consist essentially of doped or undoped silicon. The first junction may include or consist essentially of SiGe, and the second junction may include or consist essentially of at least one III-V material. The first junction and/or the second junction may have a threading dislocation density of less than approximately 10⁷ cm⁻². The substrate may include or consist essentially of a polymer and/or a metal.

In another aspect, embodiments of the invention feature a solar cell including a first junction and a second junction, either or both of which having a threading dislocation density of less than approximately 10⁷ cm⁻². The first junction includes or consists essentially of SiGe, and the second junction includes or consists essentially of at least one III-V material. A contact layer including or consisting essentially of an alloy of silicon and a metal is disposed over a portion of the second junction. The first junction may be disposed over, and even in direct contact with, a substrate including or consisting essentially of silicon. The contact layer may be disposed in direct contact with the second junction. A layer including or consisting essentially of at least one III-V material may be disposed between the contact layer and the second junction. The layer may be substantially free of silicon, and/or may include or consist essentially of at least one of GaP or AlP.

In yet another aspect, embodiments of the invention feature a method of semiconductor formation. A substrate including or consisting essentially of silicon is provided in a reactor. A first layer including or consisting essentially of doped or undoped SiGe is formed on the substrate. After forming the first layer, and without exposure to an outside ambient therebetween, a second layer including or consisting essentially of a doped or undoped III-V material is formed on the first layer. The second layer is substantially free of stacking faults and/or anti-phase defects. The first layer and/or the second layer may be formed over substantially all of the top surface of the substrate.

Embodiments of the invention may include one or more of the following features in any of a variety of combinations. The interface between the first layer and the second layer may be substantially free of oxygen, carbon, and/or misfit dislocations. The second layer may include or consist essentially of GaAsP. The first layer and the second layer may be substantially lattice-matched to each other, and/or may be lattice mismatched to Ge by at least approximately 1%. A tunnel junction may be formed between the first layer and the second layer by autodoping, e.g., mutual autodoping. The second layer may be substantially free of Al. The threading dislocation density of the second layer may be less than or approximately equal to the threading dislocation density of the first layer. During formation of the first layer, the first layer may be intentionally doped by incorporation of at least one element not found in the second layer, e.g., boron.

In a further aspect, embodiments of the invention feature a method of forming a solar cell. A structure including or consisting essentially of a substrate, a first junction over the substrate, and a second junction over the first junction is provided, the structure is bonded to a handle substrate, and at least a portion of the substrate is removed. The substrate includes or consists essentially of silicon, the first junction includes or consists essentially of at least one III-V material, and the second junction includes or consists essentially of SiGe. The first junction and/or the second junction may have a threading dislocation density of less than approximately 10⁷ cm⁻².

Embodiments of the invention may include one or more of the following features in any of a variety of combinations. The structure may include a template layer disposed between the substrate and the first junction. At least a portion of the template layer may be removed after the structure is bonded to the handle substrate. The template layer may include or consist essentially of SiGe. The structure may include a cap layer including or consisting essentially of doped or undoped silicon over the second junction. A contact layer including or consisting essentially of an alloy of doped or undoped silicon and a metal may be disposed over the second junction. A metallization layer (that may include or consist essentially of a metal) may be disposed over the second junction. The handle substrate may include or consist essentially of a non-semiconductor material and/or may be substantially polycrystalline or amorphous. The handle substrate may include or consist essentially of a metal and/or a polymer.

In yet a further aspect, embodiments of the invention feature a solar cell including a handle substrate, a first junction disposed over the handle substrate, and a second junction disposed over the first junction. The handle substrate includes or consists essentially of a non-semiconductor material, the first junction includes or consists essentially of single-crystalline SiGe, and the second junction includes or consists essentially of at least one single-crystalline III-V material. The first junction and/or the second junction may have a threading dislocation density of less than approximately 10⁷ cm⁻². The handle substrate may be substantially polycrystalline or amorphous, and/or may include or consist essentially of a metal and/or a polymer. A cap layer including or consisting essentially of doped or undoped silicon may be disposed between the first junction and the handle substrate. A contact layer including or consisting essentially of an alloy of doped or undoped silicon and a metal may be disposed between the handle substrate and the first junction or the cap layer. A metallization layer including or consisting essentially of a metal may be disposed between the handle substrate and the first junction, contact layer, or cap layer. A template layer may be disposed over the second junction. The template layer may include or consist essentially of SiGe and/or may include or consist essentially of a uniform-composition portion and a graded-composition portion. A cap layer including or consisting essentially of Si and/or SiGe (doped or undoped) may be disposed over the second junction.

In an aspect, embodiments of the invention feature a solar cell including a substrate, a first junction disposed over substantially all of a top surface of the substrate, a second junction disposed over substantially all of a top surface of the first junction, a cap layer disposed over the second junction in a first region, and a contact disposed over the second junction in a second region adjoining the first region. The substrate and the cap layer include or consist essentially of doped or undoped silicon. The first junction includes or consists essentially of SiGe, and the second junction includes or consists essentially of at least one III-V material.

Embodiments of the invention may include one or more of the following features in any of a variety of combinations. The cap layer may consist of doped or undoped silicon. A third junction including or consisting essentially of at least one III-V material different from the III-V material of the second junction and having a bandgap different from the bandgaps of the first and second junctions may be disposed over substantially all of a top surface of the second junction. The first junction and the second junction may each have a lattice mismatch to Ge of greater than approximately 1%. The metal may include or consist essentially of titanium, copper, nickel, cobalt, platinum, and/or tungsten. A template layer including or consisting essentially of a graded-composition layer may be disposed over substantially all of the top surface of the substrate and between the substrate and the first junction, and the top surface of the template layer may be substantially lattice-matched to the first junction. The spectral sensitivity of the solar cell may be less than approximately 6% for a change in spectrum from AM0 to AM1.5. The first junction may be partitioned into at least two sub-cells, each sub-cell including or consisting essentially of SiGe having a different Ge concentration than the other sub-cells. The interface between the first junction and the second junction may include or consist essentially of a tunnel junction. The tunnel junction may include or consist essentially of SiGe and GaAsP. The SiGe may be doped either n-type or p-type, and the GaAsP may be doped the type opposite that of the SiGe. The tunnel junction may include or consist essentially of a first layer adjacent the first junction and a second layer adjacent the second junction. The first layer may be doped with a first dopant species, and the second junction may be substantially free of the first dopant species. The second layer may be doped with a second dopant species present in the first junction as a non-doping element (e.g., an isoelectronic element such as Si and/or Ge). A portion of the cap layer may be disposed beneath the contact in the second region. The threading dislocation density of the cap layer may be higher than the threading dislocation density of the first junction by at least an order of magnitude, or even two orders of magnitude. The solar cell may include a plurality of additional first regions and a plurality of additional second regions, the first regions and the second regions collectively extending over the total area of the top surface of the substrate, and the total area of the second regions may be less than approximately 25% (or even less than approximately 10%) of the total area of the top surface.

In another aspect, embodiments of the invention feature a method of power generation. A solar cell is provided on a platform and exposed to solar radiation, thereby generating an electric current. The solar cell includes or consists essentially of a substrate, a first junction disposed over substantially all of a top surface of the substrate, a second junction disposed over substantially all of a top surface of the first junction, a cap layer disposed over the second junction in a first region, and a contact disposed over the second junction in a second region adjoining the first region. The first junction includes or consists essentially of SiGe, the second junction includes or consists essentially of at least one III-V material, the cap layer includes or consists essentially of doped or undoped silicon, and the contact includes or consists essentially of an alloy of doped or undoped silicon and a metal. The substrate may include or consist essentially of silicon, a polymer, and/or a metal. The platform may be selected from the group consisting of a satellite disposed over a substantial portion of the earth's atmosphere, a concentrator system, and an aerial vehicle. Exposing the solar cell to solar radiation may include or consist essentially of exposing the solar cell of spectra ranging from approximately AM1 to greater than approximately AM1.5. The spectral sensitivity of the solar cell may be less than approximately 6%.

In yet another aspect, embodiments of the invention feature a method of forming a solar cell. A first junction including or consisting essentially of SiGe is formed over substantially all of the top surface of a substrate including or consisting essentially of silicon. A second junction including or consisting essentially of at least one III-V material is formed over substantially all of the top surface of the first junction. A cap layer including or consisting essentially of doped or undoped silicon is formed over substantially all of the top surface of the second junction. A metal is formed over only a portion of the top surface of the cap layer. The metal is reacted with the cap layer to form a contact layer disposed over the second junction, the contact layer including or consisting essentially of an alloy of doped or undoped silicon and the metal.

Embodiments of the invention may feature one or more of the following features in any of a variety of combinations. Forming the first junction and forming the second junction may include or consist essentially of epitaxial deposition in a single reactor with substantially no exposure of the substrate to oxygen therebetween. At least a portion of the substrate may be removed by thinning and/or waffling. A third junction including or consisting essentially of at least one III-V material different from the III-V material of the second junction and having a bandgap different from the bandgaps of the first and second junctions may be formed over substantially all of the top surface of the second junction. An unreacted portion of the cap layer may be removed. After reacting the metal layer, an unreacted portion of the cap layer may remain disposed between the second junction and the contact. A tunnel junction may be formed between the first junction and the second junction. Forming the tunnel junction may include or consist essentially of intentional introduction of a first dopant species during epitaxial growth and autodoping of a second dopant species having a polarity opposite that of the first dopant species. Forming the tunnel junction may include or consist essentially of mutual autodoping of first and second dopant species having opposite polarities.

In yet another aspect, embodiments of the invention feature a method of forming a solar cell. A structure including or consisting essentially of a substrate, a first junction having a first bandgap disposed over the substrate, and a second junction having a bandgap smaller than the first bandgap disposed over the first junction. The structure is bonded to a handle substrate and at least a portion of the handle substrate is removed. The first junction and/or second junction may be disposed over substantially all of the top surface of the substrate. The first junction may include or consist essentially of at least one III-V material and the second junction may include or consist essentially of SiGe. The structure may include a template layer disposed between the substrate and the first junction, the template layer including or consisting essentially of a graded-composition layer. The entire substrate may be removed, and at least a portion of the template layer may be removed thereafter. Prior to bonding the structure to the handle wafer, the structure may include (i) a cap layer disposed over the second junction, the cap layer including or consisting essentially of doped or undoped silicon, and/or (ii) a contact layer disposed over the second junction, the contact layer including or consisting essentially of an alloy of doped or undoped silicon and a metal. The cap layer and/or the contact layer may be disposed over substantially all of a top surface of the second junction. After at least a portion of the substrate is removed, a contact may be formed over the first junction over a surface opposed to the handle wafer. Prior to forming the contact, a cap layer may be formed over the first junction over the surface opposed to the handle wafer. The cap layer may include or consist essentially of doped or undoped silicon, and forming the contact may include or consist essentially of reacting at least a portion of the cap layer with a metal. The handle substrate may include or consist essentially of a polymer and/or a metal. The second junction may include a graded-composition layer. The threading dislocation density of the second junction may be higher than the threading dislocation density of the first junction by at least a factor of two, by at least a factor of five, or even by at least an order of magnitude. The structure may contain no bonded interface (e.g., between the first and second junctions) prior to bonding the structure to the handle substrate.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the term “substantially” means±10%, and in some embodiments, ±5%, and the term “consists essentially” (unless otherwise defined) precludes materials contributing to function.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic cross-sectional diagram of an encapsulated solar cell formed in accordance with various embodiments of the invention;

FIG. 2 is a schematic cross-sectional diagram of the structure of FIG. 1 after the addition of a conductive material for contact formation, in accordance with various embodiments of the invention;

FIGS. 3-5 are schematic cross-sectional diagrams of various embodiments of the structure of FIG. 2 after contact formation;

FIG. 6 is a schematic cross-sectional diagram of the structure of FIG. 3 after front-side and backside metallization in accordance with various embodiments of the invention;

FIG. 7 is a schematic cross-sectional diagram of the structure of FIG. 6 with portions of the substrate removed in accordance with various embodiments of the invention;

FIG. 8 is a partial plan-view schematic diagram of the bottom surface of the structure of FIG. 7 in accordance with various embodiments of the invention;

FIGS. 9A-9D are schematic cross-sectional diagrams of an alternate process sequence utilized to form an encapsulated solar cell in accordance with various embodiments of the invention;

FIG. 10 is a schematic cross-sectional diagram of a concentrator system incorporating a solar cell formed in accordance with various embodiments of the invention;

FIG. 11 is a perspective illustration of a satellite incorporating a solar cell formed in accordance with various embodiments of the invention;

FIG. 12 is a perspective illustration of an aerial vehicle incorporating a solar cell formed in accordance with various embodiments of the invention; and

FIG. 13 is a schematic cross-sectional diagram of an exemplary encapsulated solar cell prior to contact formation in accordance with various embodiments of the invention.

### DETAILED DESCRIPTION

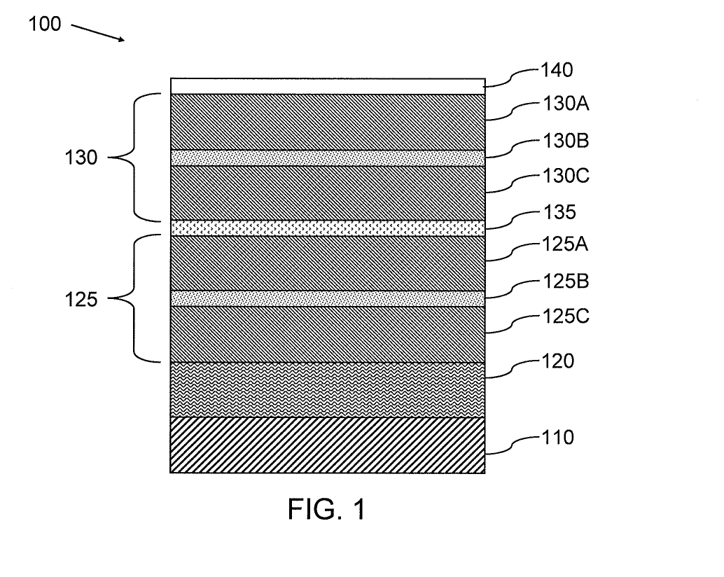

Embodiments of the present invention feature high-efficiency, multi-junction solar cells having both SiGe- and III-V-based cells, which are typically embedded into silicon (Si), to create a “Si-encapsulated cell,” or SEC. Referring to FIG. 1, in various embodiments, the formation of an SEC 100 begins with the provision of a substrate 110. Substrate 110 preferably includes (at least on its surface) or consists essentially of Si. Substrate 110 may be, for example, a silicon-on-insulator (SOI) wafer, and/or may have a layer of Si (having, e.g., a different doping level than that of the bulk of the substrate) disposed on a top surface thereof (e.g., in the manner of an “epi-Si wafer”). For example, substrate 110 may include or consist essentially of a layer of Si over another material (which may be polycrystalline), such as silicon carbide. In an embodiment, substrate 110 consists essentially of, or even consists of, Si and various n-type and/or p-type dopants. In another embodiment, substrate 110 includes or consists essentially of a non-Si material that is compatible with Si microelectronics fabrication processes (to which III-V substrates such as GaAs and certain metals such as gold (Au) are typically anathema due to contamination concerns); suitable materials include, e.g., quartz or glass. Such a non-Si-containing substrate 110 may have a top layer of Si disposed thereon. The diameter of substrate 110 may be larger than approximately 100 mm, larger than approximately 200 mm, larger than approximately 300 mm, or even larger than approximately 450 mm. Since in preferred embodiments, substrate 110 includes or consists essentially of Si, substrate 110 generally has a diameter larger than would be possible were a compound semiconductor substrate (e.g., one including or consisting essentially of a III-V or a II-VI material) utilized.

In a preferred embodiment, substrate 110 does not include an active solar-cell junction (i.e., does not include a p-n or p-i-n junction designed to convert incident light into electrical current). Herein, omitting an active solar-cell junction is understood to connote the absence of an intentionally formed p-n junction in a particular material or layer. Solar photons may still be absorbed in such a layer, particularly if it has an appreciable thickness. Moreover, unintentional junctions may be formed in the material by, e.g., autodoping during growth of the material and/or other layers. At least the top surface of substrate 110 may have substantially a (100) crystalline orientation (e.g., substrate 110 may be a (100) Si wafer), although in various embodiments, at least the top surface of substrate 100 is “miscut,” i.e., deliberately misoriented (or “tilted”) away from a major crystallographic plane such as (100). In an embodiment, substrate 110 includes or consists essentially of a (100) Si substrate miscut between approximately 2° and approximately 10° along an in-plane <110> crystallographic direction. In a preferred embodiment, the miscut is approximately 6° along an in-plane <110> crystallographic direction.

In various embodiments, a template layer 120 is disposed over substrate 110. Template layer 120 typically mediates lattice mismatch between substrate 110 and the subsequently added solar-cell junctions (as further described below), thus minimizing the defect density in such junctions. Thus, preferably, a bottom portion of template layer 120 is substantially lattice-matched (as utilized herein, “substantially lattice-matched” may refer to having a lattice-parameter difference less than the approximate difference between the lattice parameters of Ge and GaAs, having a lattice-parameter difference less than approximately 0.2%, or a lattice-parameter difference even less than approximately 0.1%) to the top surface of substrate 110, and a top portion of template layer 120 is substantially lattice-matched to a solar-cell junction formed thereover. In an embodiment, template layer 120 includes or consists essentially of SiGe or GaAsP, at least a portion of which may be graded in composition as a function of the thickness of template layer 120. The thickness of template layer 120 may range between approximately 1 micrometer (μm) and approximately 10 μm, and template layer 120 may include at least one n-type and/or p-type dopant. The graded portion of template layer 120 may have a grading rate (i.e., the rate of change of one component of the layer as a function of position within the layer thickness, e.g., the percentage change of germanium (Ge) as a function of height through the thickness of a SiGe graded layer) ranging between approximately 5%/μm and approximately 50%/μm, and preferably between approximately 10%/μm and approximately 25%/μm. Template layer 120 may include an upper portion having a substantially uniform composition, which may be the approximate composition of an upper portion of a graded portion of template layer 120. The upper, uniform-composition portion may have a thickness ranging between approximately 0.5 μm and approximately 2 μm. In a preferred embodiment, the thickness of the uniform-composition portion is approximately 1 μm. As detailed below, preferred embodiments feature a SiGe-based junction above or incorporated within (i.e., formed as at least a portion of) the uniform-composition portion of template layer 120. Preferably, the doping level of template layer 120 is of the same type (i.e., either n-type or p-type) and of approximately the same concentration as that of substrate 110 to facilitate electrical connection therethrough.

In a particular embodiment, template layer 120 includes or consists essentially of graded SiGe topped with a layer of Ge or uniform-composition SiGe (e.g., Si_{0.3}Ge_{0.7}), which is approximately lattice-matched to certain III-V semiconductor materials such as GaAs or InGaP. In preferred embodiments in which template layer 120 includes or consists essentially of SiGe, the upper surface of template layer 120 preferably has a Ge concentration ranging between approximately 65% and approximately 95%, more preferably between approximately 75% and approximately 90%, and even more preferably between approximately 80% and approximately 90%. Template layer 120 is preferably formed as a continuous layer over and in direct contact with substantially all of the top surface of substrate 110. (Herein, layers are considered to be formed over “substantially all of a top surface” of a substrate or an underlying layer even if such formation leaves any negligible “gap,” e.g., at an edge of the substrate due to imperfect layer formation or edge exclusion dictated by a particular process or particular processing equipment; however, layers formed only in specific patterned areas on a substrate are generally not considered to be over substantially all of a top surface, even if the spaces between areas are relatively small.) Template layer 120 may be formed by, e.g., an epitaxial deposition process such as chemical-vapor deposition (CVD). Metallorganic CVD (MOCVD) is typically used only for formation of III-V-based semiconductor materials. However, in an embodiment, template layer 120 (as well as other layers described herein) is formed in an MOCVD reactor capable of forming Si, SiGe, Ge, and III-V-based semiconductor materials. The reactor may be a close-coupled shower-head reactor in which gaseous precursors travel only a short distance (e.g., approximately 1 cm) from an unheated injection point to a substrate heated to a desired deposition temperature. In various embodiments, the growth rate of template layer 120 (and/or other layers described herein) is greater than approximately 500 nm/min, or even greater than approximately 700 nm/min. Template layer 120 (and/or other layers described herein) may be grown at a growth temperature between approximately 600° C. and approximately 900° C., e.g., approximately 750° C., at a growth pressure between approximately 10 Torr and approximately 200 Torr, e.g., approximately 100 Torr. Template layer 120 and/or junction 125 may be formed by flowing SiH₄ and GeH₄ in H₂ carrier gas. Template layer 120 preferably has a threading dislocation density (e.g., intersecting a top surface thereof) of less than approximately 10⁷/cm², and preferably less than approximately 10⁶/cm² or even less than approximately 10⁵/cm², as measured by plan-view transmission electron microscopy (TEM) or etch-pit density (EPD) measurements.

In certain embodiments, template layer 120 includes or consists essentially of a layer of uniform composition disposed directly over substrate 110. For example, template layer 120 may include or consist essentially of SiGe, GaAsP, InGaP, or GaAs formed directly over substrate 110 by, e.g., wafer bonding. However, direct growth of such materials with high lattice mismatch (e.g., greater than approximately 1-2%) to substrate 110 is not preferred due to the elevated defect levels that may result in template layer 120 and/or subsequently formed layers.

Disposed over template layer 120 (or within a uniform-composition portion thereof, as described above) is a junction 125, which may include a p-type-doped subregion 125A, an intrinsically doped subregion 125B, and an n-type-doped subregion 125C. In various embodiments, subregion 125B is omitted. Junction 125 is preferably formed over substantially the entire top surface of template layer 120 (and therefore over substantially the entire top surface of substrate 110). The doping types of subregions 125A and 125C may be swapped, and the doping type of subregion 125C preferably matches that of template layer 120 and/or substrate 110. In some embodiments, a p-type-doped subregion 125A and an n-type-doped subregion 125C provides SEC 100 with more resistance to radiation damage (and thus, increased suitability for non-terrestrial applications) than embodiments in which the doping types of these subregions are swapped. Junction 125 includes or consists essentially of SiGe, e.g., SiGe having a Ge composition between approximately 65% and approximately 95%. In preferred embodiments, junction 125 is substantially lattice-matched to at least one III-V-based junction formed thereover (as described below). Herein, consisting essentially of SiGe does not preclude the presence of dopants and/or other charge-modifying agents therein, but does preclude the presence of other semiconductor materials, e.g., III-V semiconductors. For example, the layers of junction 125 may consist essentially of doped or undoped SiGe, e.g., SiGe having a Ge composition of approximately 70% that is substantially lattice-matched to InGaP or GaAsP. In various embodiments, an upper portion of template layer 120 and at least a portion of junction 125 (and/or any subsequently added junction 130 described below) have a lattice mismatch to Ge of greater than approximately 1%.

Disposed over junction 125 is at least one junction 130, which may include a p-type-doped subregion 130A, an intrinsically doped subregion 130B, and an n-type-doped subregion 130C. In various embodiments, subregion 130B is omitted. As utilized herein, a “junction” (or “cell,” or in some instances, a “sub-cell”) refers to at least two layers having different (e.g., opposite) doping polarities that may be in direct contact, e.g., a p-n junction or a p-i-n junction. Junction 130 is preferably formed over substantially the entire top surface of junction 125 and/or template layer 120 (and therefore over substantially the entire top surface of substrate 110). The doping types of subregions 130A and 130C may be swapped, and the doping type of subregion 130C preferably matches that of template layer 120 and/or substrate 110. In some embodiments, a p-type-doped subregion 130A and an n-type-doped subregion 130C provides SEC 100 with more resistance to radiation damage (and thus, increased suitability for non-terrestrial applications) than embodiments in which the doping types of these subregions are swapped. Junction 130 includes or consists essentially of at least one compound semiconductor (e.g., III-V) material, such as GaAs, InGaP, AlGaP, AlGaAs, GaP, AlGaSb, GaSb, InP, InAs, InSb, InAlGaP, GaAsP, GaSbP, AlAsP, AlSbP, and/or any alloys or mixtures thereof, although Al-containing materials are not preferred. Herein, consisting essentially of at least one compound semiconductor material does not preclude the presence of dopants and/or other charge-modifying agents therein. Preferably, junction 130 does not include elemental Si or alloys or mixtures thereof, except for silicon utilized as an n-type or p-type dopant. In some embodiments, junction 130 is substantially lattice-matched to junction 125; however, in other embodiments the two junctions are lattice-mismatched due to, e.g., junction 125 incorporating a graded-composition layer therein (as described below). In such embodiments, junction 125 may have a larger lattice constant that that of junction 130. For example, junction 125 may include or consist essentially of SiGe having a Ge concentration ranging between approximately 75% and approximately 95%, more preferably between approximately 80% and approximately 90%, while junction 130 may have a lattice constant substantially lattice-matched to SiGe having a Ge concentration of approximately 70%.

Solar cells formed in accordance with various embodiments of the invention may incorporate a junction 125 and one or more junctions 130 having bandgaps optimized for collection of solar photons in terrestrial or space applications. Conventional state-of-the-art triple-junction cells are fabricated on Ge substrates (i.e., on the Ge lattice constant), thus limiting the bandgaps of the subcells to 0.67 eV (Ge), 1.4 eV (GaAs) and 1.8 eV (InGaP). The conventional bandgap combination is far from optimal, resulting in a maximum AM0 efficiency of less than approximately 30%. Embodiments of the invention utilize a SiGe-based template layer 120 to access a wide range of lattice constants and bandgaps, including those more optimal for harnessing the energy of the AM0 solar spectrum: 0.9 eV (e.g., SiGe), 1.55 eV (e.g., GaAsP or GaPSb) and 2.3 eV (e.g., InGaP). Unlike conventional bulk substrates such as Si, Ge, or GaAs, SiGe spans a wide range of lattice constants, allowing for a high degree of flexibility in designing the bandgap profile for a multi-junction solar cell. In addition, SiGe itself provides a favorable bandgap (approximately 0.9 eV) for the bottom cell for multi-junction cells optimized for the AM0 and AM1.5 spectrum. Compared to materials systems such as pure Ge and InGaAs, SiGe enables the largest bandgap range and is the only system that spans the bandgaps required to make the most efficient AM0 and AM1.5 cells.

Embodiments of the invention achieve a short-circuit current density (J_{sc}) of >40 mA/cm². Compared to the Ge bottom cell of a conventional triple junction, the SiGe-based junction 125 increases the open-circuit voltage (V_{oc}) by a factor of two with no reduction in current for SEC 100, i.e., junction 125 produces enough current that it does not limit the other junctions in the structure. The excess current also enables the use of a partitioned junction 125. This approach allows the photocurrent to be divided among two smaller cells, i.e., two “junctions” 125, each having subregions 125A and 125C (and optionally 125B) in which the photon-absorbing base region (i.e., subregion 125A) is thinner than in a SEC 100 having a non-partitioned junction 125. The partitioned “junctions” may include or consist essentially of SiGe having different Ge concentrations. With cell partitioning, the photocurrent generated by junction 125 is divided approximately equally among two or more partitioned “sub-cells” while still providing sufficient current matching to the other junctions in SEC 100. For example, an optimized SEC 100 having junction 125 and two junctions 130 may produce a photocurrent density of approximately 16 mA/cm² under AM0 illumination. A 0.9 eV junction 125 incorporated in a 0.9 eV/1.55 eV/2.3 eV SEC 100 (optimized for AM0 illumination) may produce 32 mA/cm² if allowed to absorb the remaining spectrum after the solar illumination passes through the upper junctions 130. This available photocurrent may be partitioned between two SiGe subcells, each producing approximately 16 mA/cm². The junction 125 may even be partitioned into more than two such subcells. Such structures generally result in a fourfold increase in V_{oc} beyond conventional solar cells on Ge substrates, meaning that up to 0.8V may be generated by the partitioned bottom junction 125 alone. (Current Ge bottom cells typically generate only about 0.2 V and waste the majority of their absorbed spectrum by generating heat instead of electric current.)

Furthermore, on the SiGe lattice constant, a 1.8-2.3 eV junction 130 may be formed without the use of Al-containing semiconductors. Although Al content tends to increase the bandgap of many semiconductors, the use of Al is of limited practical importance because the V_{oc} of solar cells that utilize Al does not correlate strongly with bandgap (likely owing to the fact that Al-containing semiconductors tend to contain a high concentration of oxygen impurities that degrades the minority carrier lifetime). Various embodiments of the present invention provide one or more junctions 130 having bandgaps ranging from approximately 1.8 eV to approximately 2.3 eV without the use of Al-containing semiconductors, providing a significant advantage over the current state of the art. For example, various embodiments of the invention enable the formation of InGaP-based junctions 130 having bandgaps greater than approximately 1.9 eV, or even greater than approximately 2.1 eV (and/or less than approximately 2.3 eV). On conventional GaAs substrates, the bandgap of InGaP-based subcells is constrained to be lower than approximately 1.9 eV, and the addition of Al thereto (in order to increase the bandgap) significantly and deleteriously shortens the carrier lifetimes therein. As utilized herein, a junction (or “cell”) substantially free of Al may refer only to the “active” portions of the junction that produce photocurrent (e.g., emitter and base layers), i.e., other layers such as “back surface field” (BSF) or “window” layers may include Al (as such Al may advantageously increase the bandgap of such layers but have no impact on the electrical performance of the junction).

Each of subregions 125A, 125B, 125C, 130A, 130B, and 130C may include or consist essentially of one layer or multiple layers having different doping levels and/or thicknesses, e.g., so-called “base” layers, “emitter” layers, “window” layers, “back surface field” (BSF) layers, etc., as these are known and defined in the art. At least subregion 125C is preferably approximately lattice-matched to an upper portion of template layer 120, and at least subregion 130C is preferably approximately lattice-matched to subregion 125A. However, in some embodiments, junction 125 may include a transition layer, e.g., a relaxed graded-composition layer, that mediates any lattice mismatch between junction 125 and junction 130. For example, junction 125 may include a SiGe layer graded to a SiGe composition different from that of junction 125 (in the manner of template layer 120) to a SiGe composition having a lattice parameter substantially lattice-matched to at least a portion of junction 130. Junctions 125, 130 preferably have threading dislocation densities (e.g., intersecting a top surface thereof) of less than approximately 10⁷/cm², and preferably less than approximately 10⁶/cm² or even less than approximately 10⁵/cm², as measured by plan-view TEM or EPD measurements. Junction 130 is also preferably at least substantially free of anti-phase boundaries (APBs), e.g., at the interface between junction 130 and junction 125 (or tunnel junction 135, described below), as measured by cross-sectional and/or plan-view TEM or EPD measurements. In certain embodiments, the use of a miscut substrate 110 facilitates the formation of a junction 130 that is substantially free of APBs. Junctions 125, 130 are preferably each formed as a continuous layer (or multiple layers) over and in direct contact with substantially all of the top surface of template layer 120 and junction 125 (or tunnel junction 135), respectively. Junctions 125, 130 may be formed by, e.g., an epitaxial deposition process such as CVD. In an embodiment, substrate 110 (e.g., having template layer 120 and junction 125 disposed thereover) is annealed (e.g., at a temperature of approximately 650° C.) prior to formation of junction 130 or other III-V semiconductor-based layers. The anneal may promote high-quality formation of junction 130 by forming a “double-step” surface on junction 125.

As shown in FIG. 1, SEC 100 may include a tunnel junction 135 at the interface between junction 125 and junction 130 (and/or between multiple junctions 130). Such a tunnel junction may include or consist essentially of a highly doped p-n junction (e.g., a p++/n++junction), in which each of the n-type-doped and p-type-doped portions is doped at a level greater than approximately 1×10¹⁹/cm³. The tunnel junction(s) may facilitate current flow between junction 125 and junction 130 and/or through multiple junctions 130 (which might otherwise form low conductivity depleted regions therebetween). In a preferred embodiment, a tunnel junction 135 between junction 125 and junction 130 includes or consists essentially of heavily doped SiGe and GaAsP layers (e.g., the SiGe layer may be heavily p-type doped and the GaAsP layer may be heavily n-type doped, or vice versa) with a substantially defect-free interface therebetween, as detailed below.

Forming a high-quality GaAsP layer on SiGe has represented a long-standing challenge. Previous attempts at forming this interface have resulted in defective GaAsP films containing dislocations, stacking faults, and/or anti-phase defects, and a high-quality GaAsP layer across an entire Si wafer (with or without SiGe thereon) has yet to be demonstrated. Embodiments of the present invention enable formation of high-quality GaAsP on SiGe (e.g., on junction 125) across an entire substrate 110 having a diameter greater than approximately 150 mm wafer, greater than approximately 200 mm, greater than approximately 300 mm, greater than approximately 450 mm, or even larger.

In an embodiment, tunnel junction 135 includes or consists essentially of a GaAsP (e.g., GaAs_{0.7}P_{0.3}) layer and a SiGe layer (e.g., Si_{0.3}Ge_{0.7}) that are substantially lattice-matched. In accordance with embodiments of the invention, the GaAsP layer is prepared in a MOCVD reactor designed for III-V and SiGe epitaxy in the same growth chamber, as described above. This avoids the exposure of the SiGe surface of junction 125 to the ambient (e.g., oxygen) and avoids deleterious contamination at the SiGe/GaAsP interface. For example, the interface between junction 125 and junction 130 (and/or any SiGe/III-V interface contemplated herein) may be substantially free of oxygen, carbon, anti-phase defects, dislocations, and/or stacking faults. Herein, an interface substantially free of oxygen and/or carbon may include either or both species at a “background” level at which they are present in adjoining layers, but will generally lack a “spike” or other increase in the levels of these elements beyond the background level. After formation of junction 125, substrate 110 may be annealed at a temperature ranging between approximately 750° C. and approximately 900° C. under a substantially hydrogen-free ambient, e.g., a N₂ ambient in order to facilitate subsequent formation of GaAsP on junction 125 with substantially no defects at an interface therebetween (or originating at such an interface). Initiation of the growth of the GaAsP layer of tunnel junction 135 may be performed at approximately 725° C. and approximately 100 mT by flowing trimethylgallium (TMGa), AsH₃ and PH₃ precursor gases in a N₂ carrier gas. The resulting GaAsP layer may be of high quality on all length scales, e.g., substantially free of dislocations or antiphase defects in XTEM and appearing specular to the eye. In various embodiments, tunnel junction 135 includes the above-described GaAsP layer and either a heavily doped SiGe layer formed above junction 125 or over a heavily doped upper region of junction 125 itself (e.g., a heavily doped upper portion of subregion 125A).

Tunnel junction 135 may include or consist essentially of a heavily doped GaAsP layer over a SiGe layer heavily doped with the opposite polarity, and each of these layers may be formed by, e.g., MOCVD, with intentional in-situ doping to introduce the dopants therein (and, as described above, the SiGe layer of tunnel junction 135 may be a heavily doped upper portion of junction 125). In such embodiments, the concentration profiles of the n- and p-type dopants within tunnel junction 135 are typically at least fairly abrupt, or even discontinuous from layer to layer, as they have not been introduced by diffusion. Furthermore, in such embodiments, the intentional dopants in each of the regions of tunnel junction 135 may be elements not present as the primary alloy constituents of the other region (e.g., the GaAsP layer may be intentionally doped with elements other than Si or Ge, and the SiGe layer may be intentionally doped with elements other than Ga, As, or P).

However, in various embodiments, autodoping or mutual autodoping is utilized during formation of tunnel junction 135. In an embodiment, a thin layer of SiGe within or above junction 125 is heavily in-situ doped p-type, e.g., with B at a concentration greater than approximately 1×10¹⁹ cm⁻³, or even greater than approximately 1×10²⁰ cm⁻³, during its formation by, e.g., MOCVD. The GaAsP layer is then grown on the heavily doped SiGe layer without intentional doping (e.g., the layer is substantially intrinsic or doped at a level less than approximately 1×10¹⁶ cm⁻³). Ge atoms from the SiGe layer diffuse into the GaAsP layer, rendering it n-type via autodoping. Depending upon the growth conditions and/or the desired level of diffusion and dopant concentration, the autodoping may occur in situ during growth of the GaAsP layer or during a subsequent anneal at elevated temperature. In such embodiments, tunnel junction 135 may include a substantially abrupt or even discontinuous doping profile adjacent to or intersecting a “diffused” doping profile (of a dopant having the opposite polarity) that continuously extends from one doped region to the other. That is, the concentration profile of the dopant introduced by autodoping may substantially continuously extend through tunnel junction 135 and may decay with a dependence that is substantially exponential or based on the Gaussian error function (and/or may be estimated by or compared to profiles defined by Fick's laws of diffusion, as known to those of skill in the art).

In some embodiments, tunnel junction 135 may even be formed via mutual autodoping. For example, for a tunnel junction 135 including SiGe and GaAsP layers, neither portion of tunnel junction 135 may be intentionally heavily doped during growth by, e.g., MOCVD. Rather, during or after formation of the layers, Ge diffuses into the GaAsP layer, rendering it n-type, and Ga preferentially diffuses into the SiGe layer, rendering it p-type. In such embodiments, both dopants in tunnel junction 135 may have diffused profiles (i.e., concentration profiles structurally different from those obtained via in-situ doping).

The Ge concentration in a GaAsP portion of tunnel junction 135 formed by autodoping may be undesirable in some embodiments of the invention (for example, the base region of the GaAsP subcell may require an n-type doping level that is lower than the Ge autodoping level). In this case, the GaAsP layer may be initiated in one growth chamber, and junction 130 may be formed in separate growth chamber of the same reactor (i.e., without exposure of the surface to ambient air), or in a different reactor altogether.

As described herein, junction 125, junction(s) 130, and/or tunnel junction 135 are preferably formed by epitaxial deposition rather than by, e.g., wafer bonding. (Although such a preference does not preclude wafer bonding utilized to form, e.g., a handle substrate over the stack of junctions, as described below, or a template layer beneath the stack of junctions, as described above.) Specifically, preferably there is no bonded interface between junction 125 and a junction 130, between multiple junctions 130, and/or proximate or within tunnel junction 135. As is known in the art, a bonded interface typically includes an array of substantially edge-type dislocations due to lattice mismatch between bonded layers and/or an array of substantially screw-type dislocations due to misorientation between bonded layers, and is structurally quite different from an interface between two materials both formed by epitaxial growth.

With continued reference to FIG. 1, disposed over junction 125 and one or more junctions 130 is cap layer 140. Cap layer 140 includes or consists essentially of a semiconductor material that is compatible with Si microelectronics fabrication processes, and in a preferred embodiment, cap layer 140 includes or consists essentially of doped or undoped Si. (Herein, a cap layer 140 including Si connotes a layer that is an alloy or mixture of Si and another element, e.g., Ge, precluding layers, e.g., III-V layers, that merely contain Si as a dopant.) In an embodiment, the thickness of cap layer 140 is less than an absorption length for solar photons in Si (e.g., less than approximately 100 nm), such that the solar response of SEC 100 is not detrimentally affected by absorption in cap layer 140. In a preferred embodiment, the thickness of cap layer 140 is less than approximately 50 nm, or even less than approximately 20 nm. In another embodiment, the thickness of cap layer 140 is greater than the absorption length for solar photons in Si, but at least a portion of cap layer 140 is removed after formation of at least one contact thereto (as further described below). After formation of cap layer 140, junction 125 and junction(s) 130 are substantially, or even completely, encapsulated by a material (e.g., Si) or materials compatible with Si microelectronics fabrication processes. Since cap layer 140 is formed after junction 130, it at least substantially coats all compound-semiconductor material disposed over substrate 110, including at the edge thereof. Thus, in accordance with embodiments of the invention, SEC 100 may be manufactured in a conventional Si fabrication facility since it outwardly resembles a Si wafer (or, at a minimum, a wafer compatible with Si-based microelectronics fabrication).

Cap layer 140 may have a sheet resistance less than approximately 1000 Ω/square. The sheet resistance of cap layer 140 may be even lower, e.g., less than approximately 100 Ω/square. In various embodiments, a cap layer 140 having such a low sheet resistance and including or consisting essentially of Si may deleteriously attenuate incident sunlight, as it may have a thickness greater than an absorption length. Thus, in various embodiments of the invention, cap layer 140 may include or consist of a “sublayer” including or consisting essentially of Si disposed above (and preferably in direct contact with) a sublayer including or consisting essentially of a low-resistance III-V material having a low absorption coefficient for solar photons, e.g., GaP or AlP. Either or both sublayers in cap layer 140 may be doped. As further described below, cap layer 140 or a portion thereof may include various crystallographic defects without substantial impact on the performance of SEC 100.

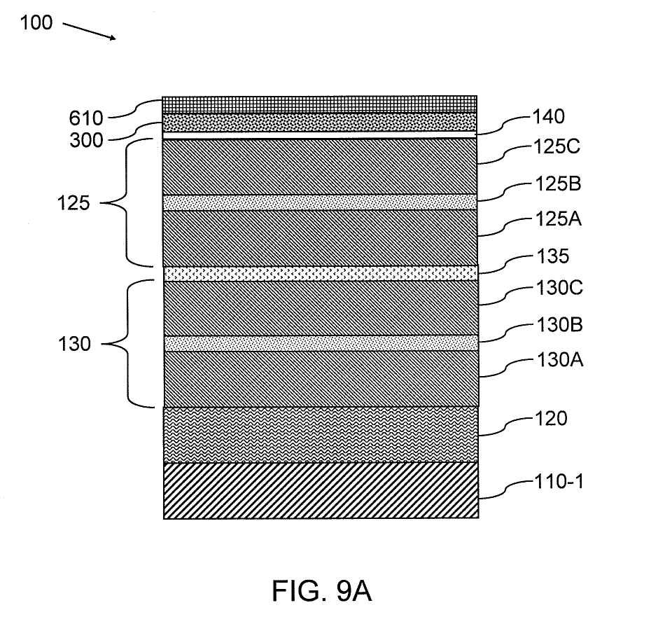

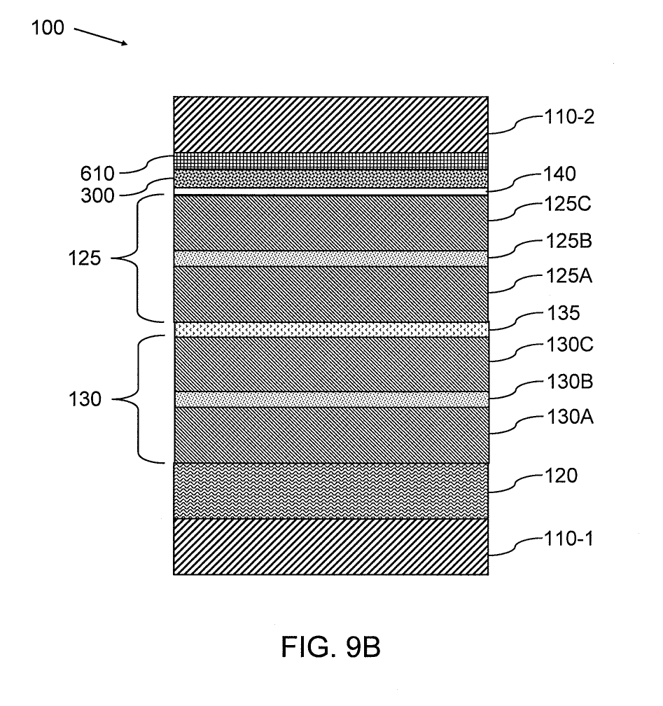

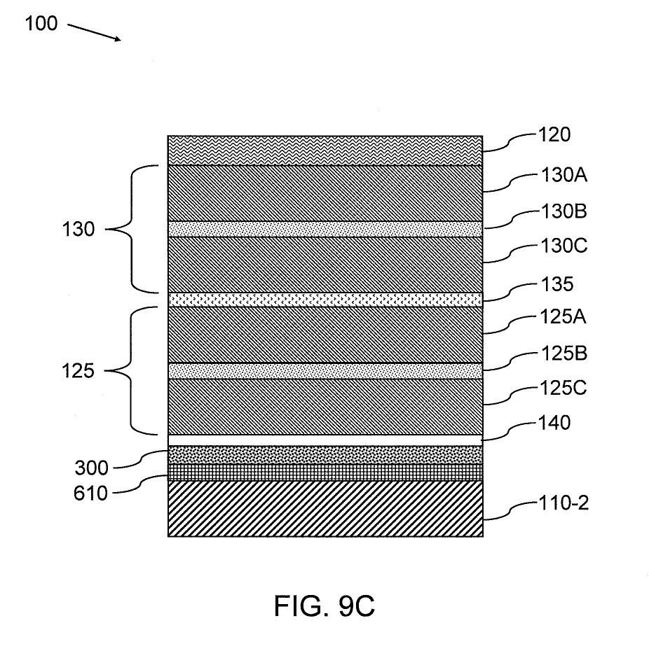

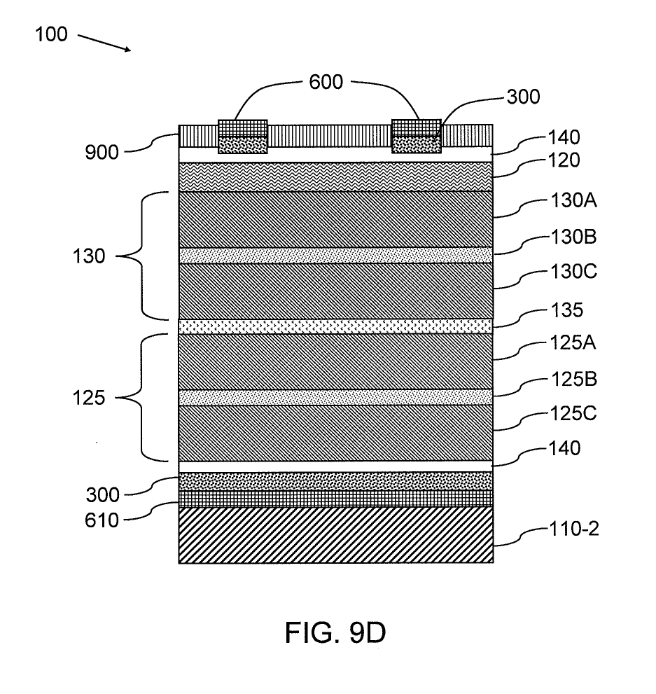

Cap layer 140 may be incorporated into the design of (and may be disposed beneath) an anti-reflection coating (which typically includes or consists essentially of silicon nitride and/or silicon dioxide, see for example FIG. 9D). In an embodiment, the anti-reflection coating and/or another protective layer provides additional encapsulation, particularly at the edge of the substrate. Cap layer 140 may be formed by, e.g., an epitaxial deposition process such as chemical-vapor deposition, and is preferably single-crystalline. In various embodiments, cap layer 140 is polycrystalline or even amorphous. In a preferred embodiment, cap layer 140 is substantially planar, notwithstanding the lattice mismatch between cap layer 140 and junction 130. In various embodiments, a thin (e.g., having a thickness ranging from approximately 1 nm to approximately 10 nm) nucleation layer (not shown) is formed between junction 130 and cap layer 140 in order to improve the nucleation and morphology of cap layer 140. The nucleation layer may include or consist essentially of a compound semiconductor material such as GaAs. In an embodiment, cap layer 140 is formed at a temperature ranging between approximately 550° C. and approximately 750° C. (e.g., approximately 650° C.), or even at lower temperatures, in order to facilitate a high degree of planarity. Cap layer 140 may be formed via use of a gaseous precursor such as silane, disilane, or trisilane to facilitate formation at sufficient growth rates at low formation temperatures. In various embodiments, at least a portion of cap layer 140 is at least partially, or even substantially completely, relaxed to its equilibrium lattice parameter. In such embodiments, cap layer 140 may include a finite concentration of misfit dislocations, threading dislocations, and/or stacking faults, and the threading dislocation density of cap layer 140 may be higher than that of junction 130 by at least approximately an order of magnitude, or even at least two orders of magnitude. Cap layer 140 may be polycrystalline and include a finite concentration of grain boundaries, even though junction 130 is preferably single-crystalline. Conventional compound semiconductor-based solar cells avoid the incorporation of severe lattice mismatch (e.g., greater than approximately 1%, greater than approximately 2%, or even greater than approximately 4%) and/or group IV-based materials due to the detrimental effects on the performance (e.g., the efficiency) of such cells due to the introduction of the above-described defects and/or due to deleterious absorption of solar photons. Unexpectedly, the relatively thin thickness of cap layer 140 (and/or the fact that at least portions of cap layer 140 may be removed during processing, as further discussed below) substantially prevents such defects from impacting the performance of SEC 100. In fact, embodiments of the invention including cap layer 140 demonstrate efficiencies substantially identical to, or even greater than, those of solar cells including junction 125 and junction(s) 130 without cap layer 140 (and either on the same or a different substrate 110, and with or without template layer 120). In preferred embodiments, substantially none of the above-described defects present in cap layer 140 propagate into junction 130 or junction 125. Preferably, cap layer 140 is single-crystalline, regardless of the lattice mismatch between it and junction 130 and the amount of lattice relaxation of cap layer 140.

Cap layer 140 may be doped with one or more n-type or p-type dopants, and the doping type and/or doping concentration of cap layer 140 preferably matches that of subregion 130A of junction 130. Typically, the doping type of cap layer 140 will be different from the doping type of substrate 110 and/or template layer 120. However, surprisingly, it has been found that a p-type-doped cap layer 140 may be utilized to form low-resistivity contacts to junction 130 (as detailed below), even if subregion 130A is n-type doped. Thus, in some embodiments, a p-type-doped cap layer 140 may be utilized over junctions 130 of either polarity orientation (i.e., p-type over n-type or vice versa). Such a layer may beneficially enable lower resistivity contacts to junction 130, as layers including or consisting essentially of Si may generally be doped p-type at higher levels than they may be doped n-type.

In some embodiments, cap layer 140 is “autodoped” either n-type or p-type by incorporation of one or more of the elements present in junction 130 (and, in such embodiments, the concentration profile of the dopant(s) in cap layer 140 may be “diffused”). Thus, if the autodoping type is the desired doping type for cap layer 140, a doped cap layer 140 may be formed without the introduction of additional dopant precursors. In contrast, if the autodoping type is that opposite the desired type for cap layer 140, the intentionally introduced dopants are provided at a higher concentration than the autodoping concentration (e.g., greater by at least approximately one order of magnitude). In certain embodiments, the autodoping concentration ranges from approximately 10¹⁹/cm³ to approximately 2×10²⁰/cm³, or even to approximately 5×10²⁰/cm³. In various embodiments, cap layer 140 may be intentionally doped at levels ranging between approximately 10²¹/cm³ to approximately 10²²/cm³.

As previously described, in various embodiments, template layer 120, junction 125, tunnel junction(s) 135, junction(s) 130, and cap layer 140 are all formed in the same deposition system with substantially no exposure to oxygen between formation of two or more of the layers. Template layer 120, junction 125, tunnel junction(s) 135, junction(s) 130, and cap layer 140 may all be formed in a single deposition chamber in the deposition system, or they may be formed in separate dedicated chambers of the same system (each layer may have its own dedicated chamber, or some layers may share a chamber). For example, one chamber of the deposition system may be utilized to form junction(s) 130 and/or other compound semiconductor-containing layers, and another chamber may be utilized to form Si- and/or SiGe-containing layers, e.g., junction 125, template layer 120, and/or cap layer 140.

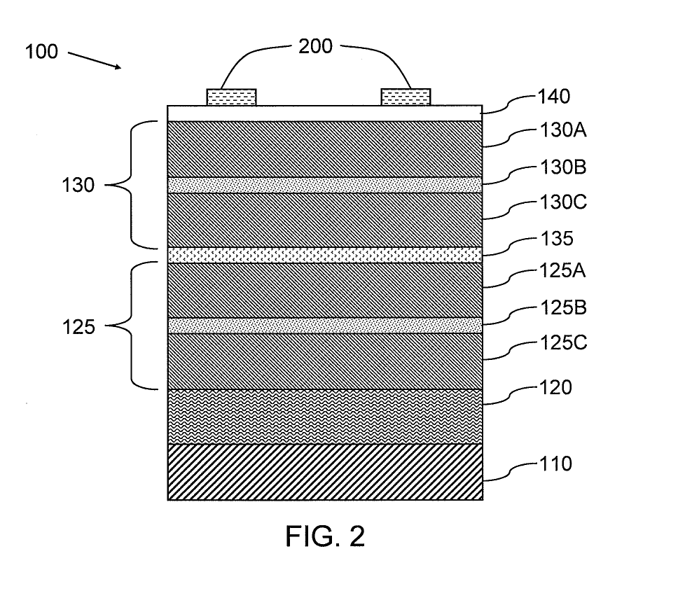

Referring to FIG. 2, contacts to junction 130 are provided via the reaction of at least a portion of cap layer 140 with a conductive material, e.g., a metal. First, metal 200 is formed over cap layer 140 in a specific pattern (e.g., a set of generally parallel lines). In an embodiment, metal 200 is formed over substantially all of the top surface of cap layer 140, patterned by conventional lithography, and etched to form the desired pattern. In another embodiment, the desired pattern is formed by a “lift-off” process, in which photoresist is patterned, metal 200 is formed thereover, and the photoresist is removed, thus carrying away metal 200 in regions where it is not desired. Metal 200 may be formed by, e.g., sputtering or evaporation. The surface of SEC 100 (e.g., cap layer 140) may be cleaned prior to the formation of metal 200 by, e.g., in-situ sputter cleaning. In some embodiments, an anti-reflective coating is disposed over regions of cap layer 140 not covered by metal 200 (and or contacts 300, described below, in the manner illustrated in FIG. 9D).

In preferred embodiments, metal 200 includes or consists essentially of a metal or metal alloy capable of forming an ohmic contact to (and via reaction with) cap layer 140 (e.g., Si) with a specific contact resistance of less than approximately 10⁻⁵ Ω-cm², or even less than approximately 10⁻⁷ Ω-cm². Metal 200 is also preferably compatible with conventional Si microelectronics processing, i.e., does not include carrier “lifetime-killing” metals such as Au or silver (Ag). In an embodiment, metal 200 does not include copper (Cu). In an embodiment, metal 200 includes or consists essentially of at least one of titanium (Ti), cobalt (Co), or nickel (Ni). In other embodiments, metal 200 includes or consists essentially of at least one of platinum (Pt), zirconium (Zr), molybdenum (Mo), tantalum (Ta), or tungsten (W).

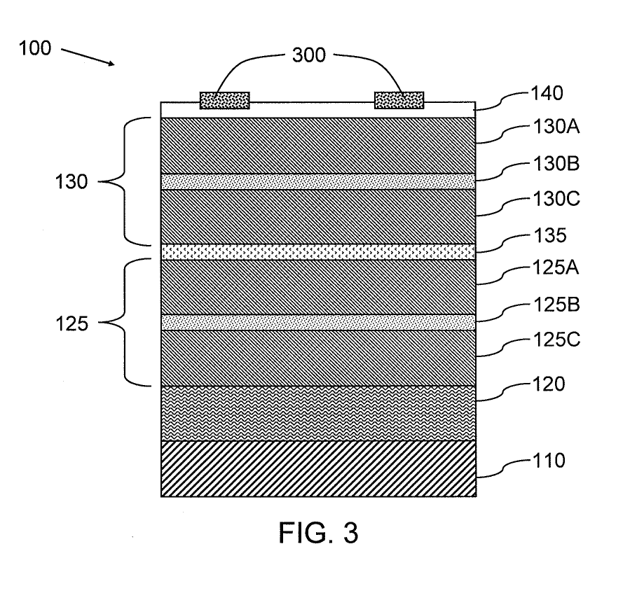

Referring to FIG. 3, contacts 300 are formed by annealing metal 200 at an elevated temperature, e.g., a temperature ranging from approximately 200° C. to approximately 700° C., for a time period ranging from approximately 10 seconds to approximately 120 seconds. During the anneal, metal 200 preferably reacts with at least a portion of cap layer 140, forming contacts 300. Thus, contacts 300 preferably include or consist essentially of a compound including elements found in cap layer 140 and metal 200, e.g., a silicide such as nickel silicide (NiₓSi₁₋ₓ). In an embodiment, each contact 300 has a specific contact resistance of less than approximately 10⁻⁵ Ω-cm², or even less than approximately 10⁻⁷ Ω-cm². Formation of contacts 300 may consume at least a portion of cap layer 140 thereunder; thus, an unreacted portion of cap layer 140 may be disposed beneath each contact 300. This unreacted portion of cap layer 140 may be thinner than portions of cap layer 140 not disposed beneath contacts 300.

In various embodiments, the contact resistance of contacts 300 may be less than approximately 10⁻⁸ Ω-cm², a level lower than is generally possible using conventional metallurgical contacts to compound semiconductor materials. Thus, SEC 100 may have a higher efficiency than a solar cell incorporating substantially similar (or even identical) junctions 125, 130 but lacking capping layer 140 (and thus utilizing standard techniques of contacting to compound semiconductor materials). Since contacts 300 on SEC 100 may have lower contact resistance (and since the lateral resistance between contacts 300 on SEC 100 may be lower, as described above), the surface area of SEC 100 covered by contacts 300 may be less than that required for a solar cell lacking capping layer 140. In an embodiment, contacts 300 (with or without the addition of a front-side conductor, as described below) cover less than approximately 25%, or even less than approximately 10% of the top surface of SEC 100. This decrease in surface coverage required for contacts 300 further increases the efficiency of SEC 100, as more incident solar photons may enter junction 130 (unblocked by contacts 300). This increase in efficiency may be greater than approximately 20%, or even larger.

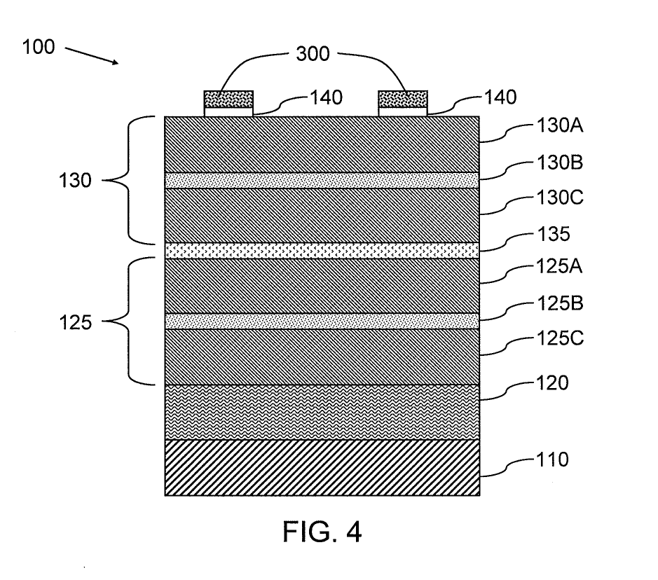

Referring to FIG. 4, in certain embodiments, at least some portions of cap layer 140 not disposed beneath contacts 300 are removed after the formation of contacts 300. (Alternatively or in addition, portions of cap layer 140 may be removed before provision of metal 200.) Thus, portions of junction 130 may be exposed between contacts 300. Removal of at least some of the unreacted portions of cap layer 140 between contacts 300 may increase performance of SEC 100 by eliminating any deleterious absorption of incident light by cap layer 140. In an embodiment, only a portion (as a function of thickness) of cap layer 140 is removed between contacts 300, leaving a cap layer 140 having a thickness thinner than its original thickness between contacts 300 and/or thinner than the thickness of the above-described unreacted portion below contacts 300. As mentioned above, the as-formed thickness of cap layer 140 may be thicker than the absorption length for solar photons in Si, and the thickness of cap layer 140 between contacts 300 may range from approximately zero to less than approximately the absorption length for solar photons in Si (e.g., less than approximately 100 nm, less than approximately 50 nm, or even less than approximately 20 nm) after removal. Having a thicker cap layer 140 may be advantageous for reducing the contact resistance of contacts 300; however, such thicker cap layers 140 may be detrimental to the performance of SEC 100 due to increased absorption of solar photons therein. Thus, the removal of portions of cap layer 140 between contacts 300 may decouple the typical trade-off between contact resistance and absorption—i.e., embodiments of the present invention enable low contact resistance with substantially no deleterious absorption by cap layer 140.

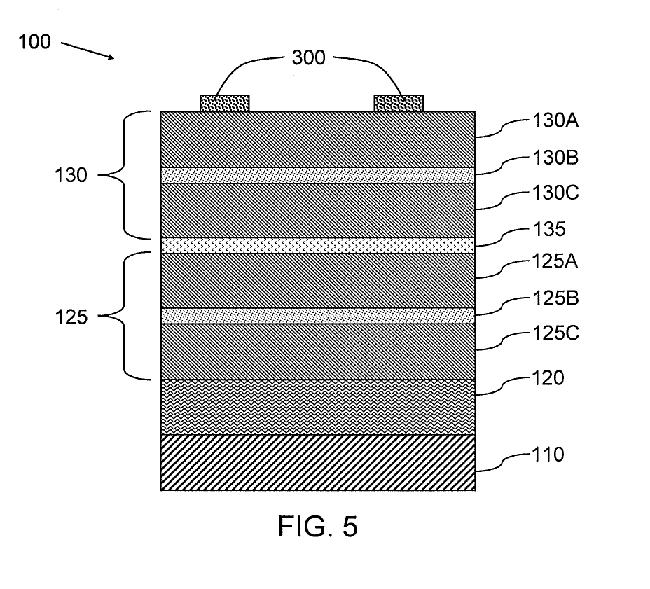

Referring to FIG. 5, in an embodiment, the reaction of cap layer 140 with metal 200 consumes substantially all of the thickness of cap layer 140 disposed beneath metal 200. Thus, contact 300 forms directly above and substantially in contact with junction 130. However, contacts 300 still preferably do not include any compound semiconductor materials found in junction 130, as junction 130 preferably does not react with metal 200 during formation of contacts 300. Although FIG. 5 illustrates an embodiment in which unreacted portions of cap layer 140 (between contacts 300) have been removed, such removal is optional, even in this embodiment. In various embodiments, the reaction of cap layer 140 with metal 200 consumes substantially all of a thickness of a silicon-based sublayer of cap layer 140, and leaves one or more lower sublayers of cap layer 140 disposed therebelow substantially unreacted. In such embodiments, contacts 300 will preferably not include any compound semiconductor materials found in the lower sublayers and/or will be in direct contact with the sublayer disposed directly beneath the silicon-based sublayer. Portions of any or all of the sublayers of cap layer 140 may be removed after the formation of contacts 300.

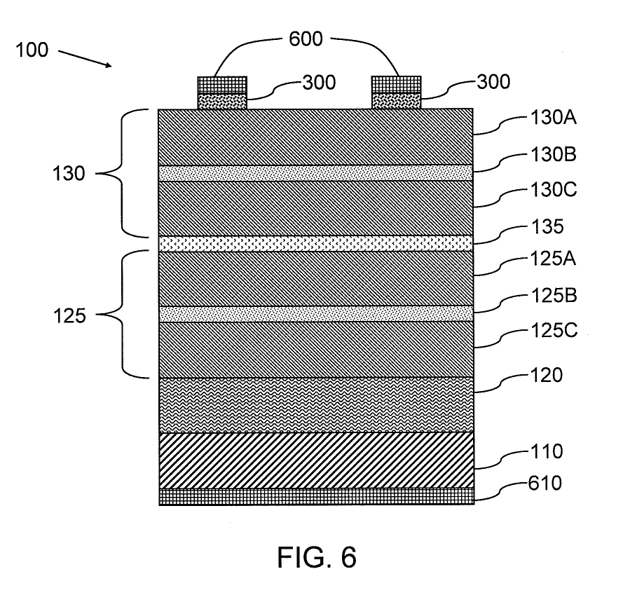

Referring to FIG. 6, metallization of SEC 100 is performed by forming front-side conductors 600 over contacts 300 and back-side conductor 610 on the bottom surface of substrate 110. Both front-side conductors 600 and back-side conductor 610 may include or consist essentially of a conductive material, such as a metal, e.g., Cu or aluminum (Al).

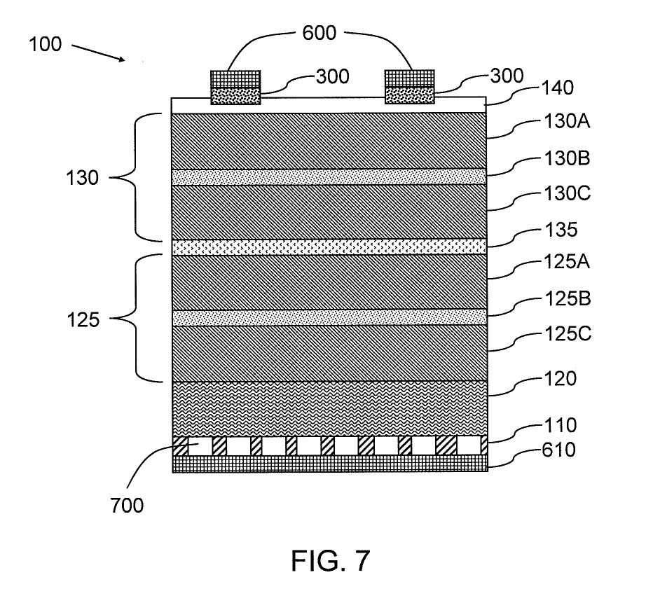

In order to reduce the weight of SEC 100 (and therefore increase the specific power of SEC 100), portions of substrate 110 may be removed before provision of back-side conductor 610. Substrate 110 may be thinned, e.g. by grinding and/or chemical-mechanical polishing (CMP), thus reducing its thickness. In some embodiments, the thickness of substrate 110 is reduced enough to make substrate 110 and SEC 100 substantially flexible. In various embodiments, a flexible SEC 100 may flex to a radius of curvature less than approximately 10 m without substantial decrease in performance. A flexible SEC 100 may be advantageously utilized in applications demanding the provision of solar cells on non-planar surfaces, as the flexible SEC 100 may substantially conform to a desired shape or topography (of, e.g., a wing, as further discussed below). FIG. 7 illustrates an SEC 100 having a thinned substrate 110. In an embodiment, a substantial portion of substrate 110 is thinned, but a portion of substrate 110 at or near its edge has a thickness larger than that of the thinned portion (and may be substantially equal to the thickness of unthinned substrate 110). Such a configuration may lend SEC 100 increased stability during handling.

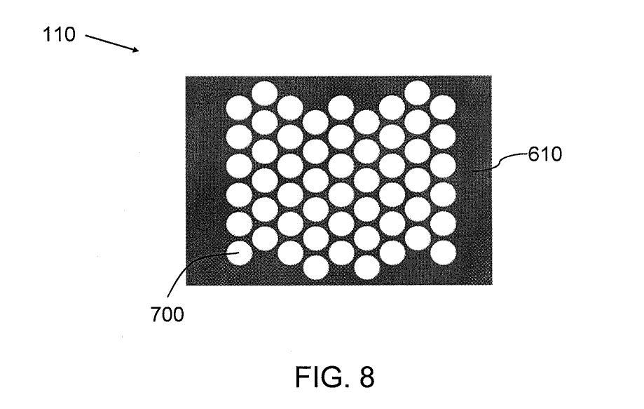

With further reference to FIG. 7, in addition to (or instead of) thinning substrate 110, portions of substrate 110 may be removed in a “waffling” process. In this process, portions of substrate 110 are removed, thus forming recesses 700. Recesses 700 may remain empty, or may be filled with a material (e.g., epoxy) having a lower density than that of substrate 110. Although FIG. 7 depicts recesses 700 as extending through substantially the entire thickness of substrate 110, in some embodiments, recesses 700 may extend only through a portion of the thickness of substrate 110. In certain embodiments, such as those used with concentrators, it is advantageous for recesses 700 to have high thermal and/or electrical conductivity, and thus, recesses 700 may be filled with a metal such as Al, Cu, and/or alloys or mixtures thereof. In various embodiments, thinning and/or waffling substrate 110 may remove more than approximately 25%, or even more than approximately 50% of the volume (and/or weight) of substrate 110. FIG. 8 illustrates a plan view of the bottom of SEC 100 after waffling of substrate 110. The embodiment of FIG. 8 shows recesses 700 formed in a six-fold symmetric “honeycomb” pattern; however, other patterns may also be advantageously utilized. Moreover, FIG. 8 depicts recesses 700 has having substantially circular cross-sections; however, other cross-sectional shapes (e.g., polygons such as hexagons) may also be advantageously utilized. Further, it should be noted that FIG. 8 depicts either a substrate 110 having a quadrilateral shape or only a quadrilaterally shaped portion of substrate 110; substrate 110 may have shape (and cross-sectional area) that is substantially non-quadrilateral, e.g., circular or hexagonal.

In certain embodiments, SEC 100 is formed, including contacts 300, front-side conductors 600, and back-side conductors 610 without external exposure of any III-V semiconductor material from junction(s) 130. Such formation facilitates the high-volume production of SEC 100 in a Si-compatible manufacturing facility with substantially no contamination of equipment therein.

FIGS. 9A-9D illustrate a method of fabricating an SEC 100 in accordance with various embodiments of the invention that facilitates removal of substrate 110, thus improving the performance and specific power of SEC 100. As shown in FIG. 9A, a template layer 120 is formed over a substrate 110-1, as previously described. The template layer 120 may include or consist essentially of SiGe and/or a III-V semiconductor material, and may include graded-composition and/or uniform-composition regions. In a specific embodiment, template layer 120 includes a graded-composition SiGe layer capped with a uniform-composition SiGe layer, and, thereon, a GaAsP initiation layer to facilitate subsequent formation of junction 130. Junctions 125, 130 and tunnel junction 135 are subsequently formed over template layer 120, but in the reverse order to that previously described with reference to FIG. 1. In various embodiments, multiple junctions 130 are formed prior to formation of junction 125. Notably, the junction having the largest bandgap is formed first, followed by the remaining junction(s) in decreasing order of bandgap. This arrangement of junctions is counterintuitive, as solar cells generally properly function only with the largest bandgap junction on top, beneath which are additional junction(s) in decreasing order of bandgap, as otherwise, portions of the solar spectrum will not be absorbed at the desired area of the cell.

However, forming the junction(s) 130 prior to forming the junction 125 may have associated benefits, particularly in embodiments in which the junction 125 has a graded-composition layer associated therewith (as described above). In such cases, where the graded-composition layer is utilized to shift the lattice parameter of junction 125 relative to that of at least one of the junction(s) 130 (and thus, making the junctions lattice-mismatched), a defect density (e.g., the threading dislocation density) of junction 125 may be higher than that of junction(s) 130. However, since junction 125 typically has a smaller bandgap than that of junction(s) 130 (and a concomitantly higher intrinsic carrier concentration), junction 125 is more tolerant of the higher defect density. That is, generally, the efficiency of a SEC 100 in which junction 125 has a higher defect density than junction(s) 130 will generally not decrease substantially, at least for threading dislocation densities of junction 125 that are less than approximately 3×10⁷ cm⁻² (e.g., in the range of approximately 5×10⁶ cm⁻² to approximately 2×10⁷ cm⁻²). In various embodiments, the defect density (e.g., the threading dislocation density) of junction 125 may be higher than that of junction(s) 130 by approximately a factor of two, approximately a factor of five, or even approximately an order of magnitude. In an embodiment, junction 125 includes or consists essentially of SiGe having a Ge composition ranging from approximately 75% to approximately 95% (e.g., ranging from approximately 80% to approximately 90%), and at least one junction 130 includes or consists essentially of at least one III-V material (e.g., GaAsP and/or InGaP) having a composition approximately lattice-matched to Si_{0.3}Ge_{0.7} (e.g., approximately GaAs_{0.7}P_{0.3} or approximately In_{0.37}Ga_{0.63}P).

In various embodiments, a cap layer 140, contact layer 300, and back-side conductor 610 are formed over this “inverted” series of junctions as previously described. In other embodiments, any of these three layers may be omitted from the structure, and contact may be made to junction 125 later in the process sequence (e.g., via or through handle substrate 110-2 described below).

As shown in FIG. 9B, the structure of FIG. 9A is bonded to a handle substrate 110-2. Handle substrate 110-2 may include or consist essentially of any of the various materials previously described for substrate 110, and preferably has a smaller thickness, smaller density, and/or higher flexibility than substrate 110-1. In exemplary embodiments, handle substrate 110-2 includes or consists essentially of a flexible polymer sheet and/or a metal foil.

Referring to FIG. 9C, substrate 110-1 is removed from the structure of FIG. 9B (now shown inverted) by, e.g., mechanical grinding, polishing, cleaving (e.g., after introduction of a cleave place by ion implantation of one or more gaseous species such as hydrogen and/or helium ions, as is known in the art), chemical etching, electrochemical etching, and/or plasma etching. Generally at least a portion of template layer 120 is also removed during removal of substrate 110-1. As shown in FIG. 9C, a portion of template layer 120 may remain above junction 130. In various embodiments, a graded portion of template layer 120 (e.g., a graded SiGe portion) is removed with substrate 110-1 and at least part of uniform-composition portion(s) of template layer 120 (e.g., a uniform-composition SiGe layer and/or a GaAsP initiation layer, as described above) remain disposed over junction 130. After this removal step, the resulting surface of the structure may be planarized by, e.g., chemical-mechanical polishing and/or ion-beam smoothing.

FIG. 9D depicts the SEC 100 fabricated in accordance with the embodiments of FIGS. 9A-9C after formation of top contacts and metallization. As shown, another cap layer 140 is formed over junction 130 (and any remaining portion of template layer 120, if present), followed by formation of contacts 300 and front-side conductors 600 as previously described. In some embodiments the additional cap layer 140 is omitted from the structure, and contacts 300 are made to the remaining portion of template layer 120; high-quality contacts 300 may be formed in such embodiments, particularly if the remaining portion of template layer 120 includes or consists essentially of an alloy containing Si and/or Ge (e.g., SiGe). In embodiments in which the remaining portion of template layer 120 includes or consists essentially of SiGe, contacts 300 may include or consist essentially of an alloy of a metal and Si, SiGe, and/or Ge (e.g., a silicide, germanosilicide, and/or germanicide). An anti-reflection coating 900 may be formed between front-side conductors 600. Anti-reflection coating 900 preferably has a thickness selected such that interference effects in the coating cause radiation reflected from its top surface to be out-of-phase with radiation reflected from the underlying semiconductor surface. The out-of-phase radiation destructively interfere with one another, resulting in substantially zero net reflected energy from SEC 100. In various embodiments, multiple anti-reflection coatings 900 are disposed over junctions 130, 125, and each anti-reflection coating 900 minimizes reflected solar energy of a particular wavelength. Anti-reflection coating 900 preferably substantially prevents carrier recombination at the surface of SEC 100, and may include or consist essentially of a dielectric material such as an oxide, nitride, and/or oxynitride, e.g., silicon nitride, silicon oxide, silicon oxynitride, indium tin oxide, and/or titanium dioxide.

The electrical performance of SEC 100 in accordance with various embodiments of the invention is at least equal to that of conventional compound semiconductor-based solar cells or conventional solar cells containing both Ge- and III-V-based junctions. As measured by certain characteristics, the performance of SEC 100 may exceed that of conventional solar cells (lacking, e.g., cap layer 140, particularly a cap layer 140 including or consisting essentially of Si, a junction 125 consisting essentially of SiGe, and/or a substrate 110 including or consisting essentially of Si) by a factor of approximately 2, a factor of approximately 4, or even a factor of approximately 10. SEC 100 may have an AM0 efficiency of greater than approximately 40% and/or an AM1.5 efficiency of greater than approximately 50%. SEC 100 may also have a fill factor ranging from approximately 0.8 and approximately 0.9 and/or an open-circuit voltage ranging between approximately 1.5 V and approximately 4.0 V (preferably ranging between approximately 3.3 V and approximately 4.0 V).

The specific power of SEC 100, e.g., SEC 100 including three junctions 130, may range between approximately 800 watts/kilogram (W/kg) and approximately 1000 W/kg, even without thinning or waffling of substrate 110. After thinning and/or waffling of substrate 110, the specific power of SEC 100 may range between approximately 1500 W/kg and approximately 3000 W/kg, or even higher. Such high specific power levels may facilitate high power outputs for weight-sensitive applications such as satellites or aerial vehicles (as further described below). The specific mass of SEC 100 may range between approximately 0.08 kg/m² and approximately 0.2 kg/m², values significantly lower than those of conventional compound semiconductor-based solar cells, even such cells formed on Ge substrates.

In various embodiments, an SEC 100 having a SiGe-based junction 125 and a GaAsP-based junction 130 has an AM1.5 efficiency of approximately 33%, approximately equal to the AM1.5 efficiency of a conventional Ge/GaAs/InGaP triple-junction solar cell. Such a conventional solar cell (and the SEC 100) may be optimized for AM1.5 efficiency. Advantageously, when such a conventional solar cell and the exemplary SEC 100 are illuminated under AM0 illumination, the efficiency of the SEC 100 drops by only approximately 2.1%, compared to a drop in efficiency of approximately 6.8% of the conventional solar cell. The lower loss of efficiency under different illumination conditions (i.e., the spectral sensitivity) of SEC 100 is a significant advantage, particularly in applications experiencing a range of illumination conditions during operation, e.g., terrestrial or aerial-vehicle applications. Thus, embodiments of the invention enable production of multi-junction cells that have at least comparable efficiencies to and lower sensitivity to spectral variation than conventional cells. Moreover, these advantages may even be harnessed with fewer junctions (e.g., two, for example one SiGe-based junction and one III-V-based junction) than are featured in conventional cells, minimizing costs and complexity. In some embodiments, SEC 100 has a spectral sensitivity less than approximately 6%, or even less than approximately 2%, for a change in illumination conditions from AM1.5 to AM1, from AM1.5 to AM0, and/or from AM1 to greater than approximately AM10. Furthermore, due to the low spectral sensitivity of SEC 100 in various embodiments of the invention, SEC 100 generally produces current during substantially all of one of the above-described changes in illumination conditions. In contrast, many conventional solar cells having three or more junctions may effectively shut down during a spectral shift, as a junction optimized for an absent (or substantially reduced) portion of the spectrum may stop producing current (and thus substantially preventing the entire cell from producing current). Thus, an SEC 100 in accordance with various embodiments of the invention may be utilized more flexibly during any of a variety of dynamic solar lighting conditions.

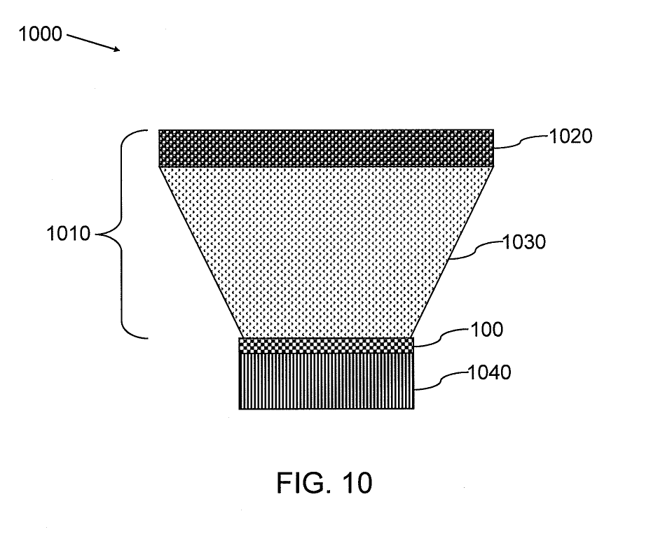

In accordance with various embodiments of the invention, SEC 100 is advantageously utilized in a variety of applications. Referring to FIG. 10, a concentrator system 1000 includes SEC 100 and, disposed thereabove, a concentrator 1010. Concentrator 1010 focuses incoming solar energy onto SEC 100, increasing the number of absorbed solar photons and increasing the amount of power (and current) generated by SEC 100. Concentrator 1010 may include several components, e.g., a lens 1020 and a focusing system 1030. Lens 1020 serves to focus solar energy impinging thereon toward an SEC 100 having a smaller cross-sectional area. Lens 1020 may be or include, e.g., a Fresnel lens or a prismatic layer, and may include or consist essentially of a substantially transparent material such as glass or plastic. Focusing system 1030 increases the amount of concentration performed by concentration system 1000 by directing (by, e.g., via internal reflection) light from lens 1020 toward SEC 100. Because concentrated solar energy (and the current generated therefrom) may substantially increase the temperature of SEC 100, SEC 100 may be disposed above and in direct contact with a heat sink 1040. Heat sink 1040 preferably includes or consists essentially of a material with high thermal conductivity, e.g., a metal or metal alloy. Concentrator system 1000 may also include other components (not pictured), such as a housing (to support and contain concentration system 1000). Concentrator 1010 may also include other components to improve light capture and focusing, such as one or more layers of organic materials (e.g., dyes) that absorb and retransmit light.

Conventional solar cells under concentration, particularly those under high concentration (e.g., greater than approximately 100 suns), typically require at least approximately 50% of their surfaces covered by metal contacts in order to adequately handle the large amounts of electrical current produced thereby. A contributing factor for the need for a large contact area is the high resistivity surface layer(s) frequently incorporated into conventional solar cell designs (e.g., surface layers incorporating materials such as InGaP). The large amount of surface coverage inhibits the performance (e.g., the efficiency) of the solar cell, as the covered area is basically unavailable for absorption of solar photons and conversion thereof into electrical power. In contrast, due to the higher conductivity of cap layer 140 on SEC 100, particularly when cap layer 140 includes or consists essentially of Si, SEC 100 experiences substantially less resistive loss at its surface. SEC 100 may include a cap layer 140 and/or contacts 300 that have a higher conductivity than surface layers of conventional compound semiconductor-based solar cells (e.g., layers including materials such as InGaP). Therefore, SEC 100 in concentration system 1000 may include a surface coverage of conductors (e.g., contacts 300 or front-side conductors 600) and/or other substantially optically opaque materials of less than approximately 25%, or even less than approximately 10%. In turn, this low amount of surface coverage enhances the amount of solar energy absorbed and converted into electrical energy by SEC 100.

Concentration system 1000 may incorporate single- or dual-axis tracking (e.g., to maximize the amount of solar photons impinging thereon as the location of the sun changes) in order to improve performance. Concentration system 1000 may enable superior concentration ratios, e.g., concentration ratios ranging between approximately 2 suns and approximately 1000 suns.

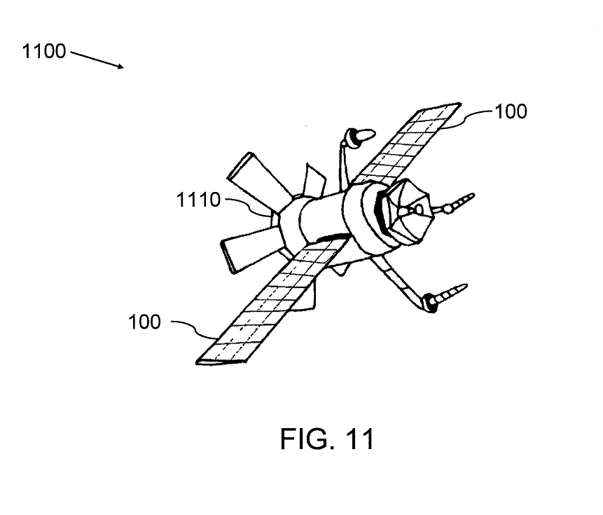

Referring to FIG. 11, SEC 100 may be advantageously utilized as a power source for a satellite 1100. The high specific power of SEC 100 enables a larger amount of power generation at a lower weight; thus, the cost and amount of propellant required to send satellite 1100 is less than if satellite 1100 incorporates conventional solar cells. Satellite 1100 may include a plurality of SECs 100, preferably pointed as directly as possible toward the sun, as well as a payload 1110. Payload 1110 may include a variety of components, including communications equipment, sensors, and the like.

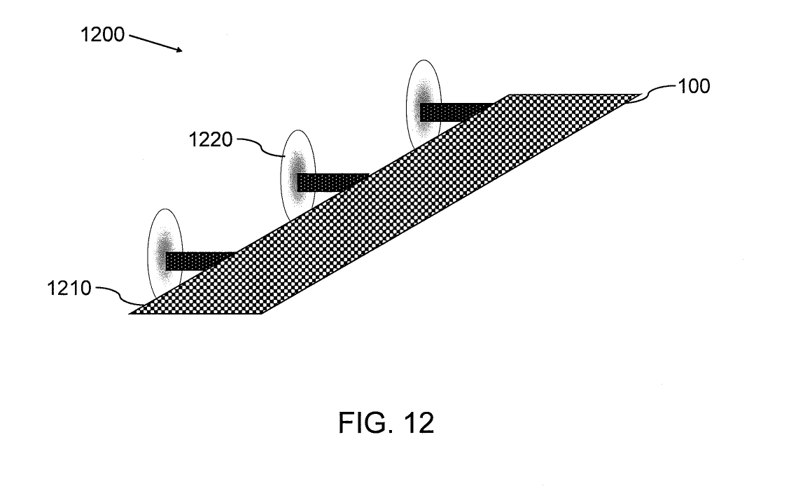

Referring to FIG. 12, SEC 100 may also be advantageously utilized as a power source for an aerial vehicle 1200. Aerial vehicle 1200, which may be manned or unmanned, includes an airframe 1210 and one or more propellers 1220 (illustrated in motion), and may be a “heavier-than-air” aircraft (as opposed to, e.g., a blimp- or dirigible-based craft) capable of flight at altitudes ranging from approximately 40,000 feet to approximately 100,000 feet above the earth's surface. Airframe 1210 may include or consist essentially of a low-density material, e.g., a composite material incorporating carbon fiber as is known in the art. Although airframe 1210 is illustrated as a roughly rectangular “wing,” airframe 1210 may take a variety of shapes, and may be substantially flat, curved, or even segmented. The wingspan of aerial vehicle 1200 may range from approximately 50 meters (m) to approximately 300 m, and the surface area of aerial vehicle 1200 and or airframe 1200 may range from approximately 100 m² to approximately 500 m². Aerial vehicle 1200 may also include (not pictured) components such as avionics and an energy storage system such as a battery or fuel cell (for, e.g., storage of energy to be used at night or in darkness). Aerial vehicle 1200 may also include structures such as fins and/or rudders for controlling its direction of travel. A plurality of SECs 100 is disposed atop airframe 1200 and covers at least approximately 50% of the surface area thereof (and even up to approximately 85% or even approximately 100%). SECs 100 provide the motive power for aerial vehicle 1200, and such power may be sufficient to power aerial vehicle 1200 for sustained flights of up to approximately 1 to approximately 5 years, 24 hours per day (e.g., power ranging from approximately 3 to approximately 8 kW, preferably approximately 5 kW). Aerial vehicle 1200 may also include a payload, e.g., sensors, cameras, and/or communications equipment, that may weigh up to approximately 1000 pounds (or even more).

### Example

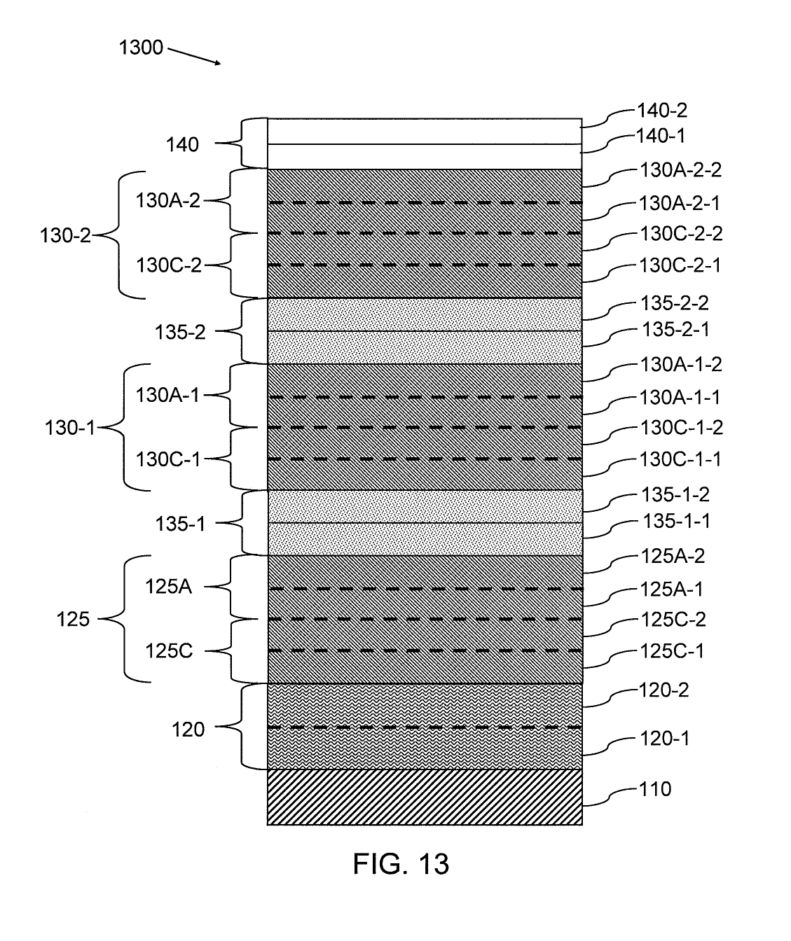

FIG. 13 depicts an exemplary SEC 1300 prior to addition of contacts 300 that incorporates a junction 125 and two junctions 130. SEC 1300 includes a substrate 110 consisting essentially of (or even consisting of) n+-doped Si. Template layer 120 includes or consists essentially of an n+-doped SiGe graded layer 120-1 (graded, e.g., from approximately 0% Ge to approximately 70% Ge) and an n+-doped Si_{0.3}Ge_{0.7} uniform composition layer 120-2. Each of junctions 125, 130-1, and 130-2 described below is preferably substantially lattice-matched to layer 120-2.

SEC 1300 includes a junction 125 including or consisting essentially of subregions 125A, 125C. Subregion 125C includes or consists essentially of an n+-doped Si_{0.3}Ge_{0.7}. BSF layer 125C-1 (having a thickness ranging between approximately 30 nm and approximately 100 nm and a doping level of approximately 2×10¹⁸/cm³) and an n-doped Si_{0.3}Ge_{0.7} base layer 125C-2 (having a thickness of approximately 2000 nm and a doping level of approximately 2×10¹⁷/cm³). Subregion 125A includes or consists essentially of a p+-doped Si_{0.3}Ge_{0.7} emitter layer 125A-1 (having a thickness of approximately 200 nm and a doping level of approximately 2×10¹⁸/cm³) and a p+-doped Si_{0.3}Ge_{0.7} window layer 125A-2 (having a thickness of approximately 20 nm and a doping level of approximately 2×10¹⁸/cm³).

Disposed between and in direct contact with junction 125 and first junction 130-1 is tunnel junction 135-1. Tunnel junction 135-1 includes a p++-doped SiGe layer 135-1-1 (having a thickness of approximately 20 nm and a doping level of approximately 2×10¹⁹/cm³) and an n+-doped GaAsP layer 135-1-2 (having a thickness of approximately 50 nm and a doping level of approximately 2×10¹⁹/cm³).

SEC 1300 also includes first junction 130-1 and second junction 130-2. First junction 130-1 includes or consists essentially of subregions 130A-1 and 130C-1. Subregion 130C-1, in turn, includes or consists essentially of an n+-doped InGaP BSF layer 130C-1-1 (having a thickness of approximately 100 nm and a doping level of approximately 2×10¹⁸/cm³) and an n-doped base layer 130C-1-2 (having a thickness of approximately 1400 nm and a doping level of approximately 2×10¹⁷/cm³) that includes or consists essentially of GaAsP and/or GaPSb. Subregion 130A-1 includes or consists essentially of a p+-doped emitter layer 130A-1-1 (having a thickness of approximately 250 nm and a doping level of approximately 2×10¹⁸/cm³) that includes or consists essentially of GaAsP and/or GaPSb, as well as a p+-doped InGaP window layer 130A-1-2 (having a thickness of approximately 40 nm and a doping level of approximately 3×10¹⁸/cm³).

Second junction 130-2 includes or consists essentially of subregions 130A-2 and 130C-2. Subregion 130C-2, in turn, includes or consists essentially of an n+-doped InAlGaP BSF layer 130C-2-1 (having a thickness of approximately 30 nm and a doping level of approximately 2×10¹⁸/cm³) and an n-doped InGaP base layer 130C-2-2 (having a thickness of approximately 450 nm and a doping level of approximately 7×10¹⁶/cm³). Subregion 130A-2 includes or consists essentially of a p+-doped InGaP emitter layer 130A-2-1 (having a thickness of approximately 50 nm and a doping level of approximately 2×10¹⁸/cm³) and a p+-doped InAlGaP window layer 130A-2-2 (having a thickness of approximately 30 nm and a doping level of approximately 4×10¹⁸/cm³).

Disposed between and in direct contact with first junction 130-1 and second junction 130-2 is tunnel junction 135-2. Tunnel junction 135-2 includes a p++-doped InGaP layer 135-2-1 (having a thickness of approximately 30 nm and a doping level of approximately 2×10¹⁹/cm³) and an n++-doped InGaP layer 135-2-2 (having a thickness of approximately 30 nm and a doping level of approximately 2×10¹⁹/cm³).

Cap layer 140 is disposed over second junction 130-2, and includes or consists essentially of a p++-doped GaAsP layer 140-1 (having a thickness of approximately 50 nm and a doping level of approximately 1×10¹⁹/cm³) and a p++-doped Si layer 140-2 (having a thickness of approximately 30 nm and a doping level of approximately 1×10¹⁹/cm³). As described above, the thickness of cap layer 140 may be reduced during the processing to form a completed SEC 1300.

SEC 1300 has an AM0 efficiency ranging from between approximately 30% and approximately 40%. SEC 1300 has an AM1.5 efficiency ranging from between approximately 40% and approximately 50%. After removal of a significant portion of the substrate 110 by, e.g., waffling and/or thinning (e.g., to a thickness of approximately 50 μm), SEC 1300 achieves a specific power greater than approximately 3000 W/kg.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1-90. (canceled)

91. A method of forming a solar cell, the method comprising:
forming, over substantially all of a top surface of a substrate consisting essentially of silicon, a first junction consisting essentially of SiGe;
forming, over substantially all of a top surface of the first junction, a second junction comprising at least one III-V material;
forming, over substantially all of a top surface of the second junction, a cap layer comprising a first layer consisting essentially of doped or undoped silicon;
forming a metal over only a portion of a top surface of the cap layer; and
reacting the metal with the cap layer to form a contact layer disposed over the second junction, the contact layer comprising an alloy of silicon and the metal.

92. The method of claim 91, wherein forming the first junction and forming the second junction comprising epitaxial deposition in a single reactor with substantially no exposure of the substrate to oxygen therebetween.

93. The method of claim 91, further comprising removing a portion of the substrate by at least one of thinning or waffling.

94. The method of claim 91, further comprising forming a third junction over substantially all of the top surface of the second junction, the third junction comprising at least one III-V material different from the III-V material of the second junction and having a bandgap different from the bandgaps of the first and second junctions.

95. The method of claim 91, further comprising removing an unreacted portion of the cap layer.

96. The method of claim 91, wherein, after reacting the metal layer, an unreacted portion of the cap layer remains disposed between the second junction and the contact.

97. The method of claim 91, further comprising forming a tunnel junction between the first junction and the second junction.

98. The method of claim 97, wherein forming the tunnel junction comprises intentional introduction of a first dopant species during epitaxial growth and autodoping of a second dopant species having a polarity opposite that of the first dopant species.

99. The method of claim 97, wherein forming the tunnel junction comprises mutual autodoping of first and second dopant species having opposite polarities.

100-110. (canceled)

111. The method of claim 91, wherein the entire cap layer consists essentially of doped or undoped silicon in contact with the second junction.

112. The method of claim 91, wherein the cap layer comprises, disposed under the first layer, a second layer consisting essentially of at least one of (i) doped or undoped GaP or (ii) doped or undoped AlP.

113. The method of claim 91, wherein the cap layer is at least partially lattice-relaxed.

114. The method of claim 91, wherein the cap layer is at least partially polycrystalline.

115. The method of claim 91, wherein the cap layer is at least partially amorphous.

116. The method of claim 91, wherein the cap layer is formed such that a resulting density of defects exceeds a defect density of the second junction, the defects comprising at least one of threading dislocations, misfit dislocations, or stacking faults.

117. The method of claim 96, wherein the portion of the cap layer disposed beneath the contact in the second region comprises a portion of the first layer.

118. The method of claim 91, wherein the first junction and the second junction each have a lattice mismatch to Ge of greater than approximately 1%.
